(19) United States
(12) Patent Application Publication
(10) Pub. No.: US 2026/0089917 A1
(43) Pub. Date: Mar. 26, 2026

(54) SEMICONDUCTOR MEMORY DEVICE

(71) Applicant: Samsung Electronics Co., Ltd., Suwon-si (KR)

(72) Inventor: Tae Jin Park, Suwon-si (KR)

(21) Appl. No.: 19/097,018

(22) Filed: Apr. 1, 2025

(30) Foreign Application Priority Data
Sep. 24, 2024 (KR) 10-2024-0128960

(51) Int. Cl. H10B 12/00; H01L 23/00; H01L 25/065

(52) U.S. Cl. CPC H10B 12/315; H10B 12/482; H10B 12/488; H10B 12/0335; H10B 12/05; H10W 80/312; H10W 80/327; H10W 90/00; H10W 90/792

(57) ABSTRACT

A semiconductor memory device includes a first data storage pattern on a substrate, a second data storage pattern spaced apart from the first data storage pattern in a first direction, a first bitline between the first and second data storage patterns, and extending in a second direction perpendicular to the first direction, a second bitline between the first and second data storage patterns, extending in the second direction, and spaced apart from the first bitline in the first direction, a wordline between the first and second bitlines, and extending in a third direction perpendicular to the first and second directions, a first active pattern between the first and second bitlines, and electrically connected to the first data storage pattern, and a second active pattern between the first and second bitlines, and electrically connected to the second data storage pattern.

### CROSS-REFERENCE TO RELATED APPLICATION

This application claims priority from Korean Patent Application No. 10-2024-0128960 filed on Sep. 24, 2024 in the Korean Intellectual Property Office, and all the benefits accruing therefrom under 35 U.S.C. § 119, the contents of which in its entirety are herein incorporated by reference.

### BACKGROUND

The present disclosure relates generally to a semiconductor memory device and, more particularly, to a semiconductor memory device including vertical channel transistors (VCTs).

To meet consumer demands for excellent performance and low cost, increasing the integration density of semiconductor memory devices is necessary. Since the integration density of semiconductor memory devices is a crucial factor in determining the product price, particularly higher integration density is required.

The integration density of two-dimensional (2D) or planar semiconductor memory devices is primarily determined by the area occupied by unit memory cells and is thus greatly influenced by the level of fine patterning technology. However, since ultra-high-cost equipment is needed for miniaturizing patterns, the integration density of 2D semiconductor memory devices, although increasing, remains limited. Accordingly, semiconductor memory devices including vertical channel transistors (VCTs), where the channels extend vertically, have been proposed.

### SUMMARY

Aspects of the present disclosure provide a semiconductor memory device with improved integration density and electrical characteristics.

However, aspects of the present disclosure are not restricted to those set forth herein. The above and other aspects of the present disclosure will become more apparent to one of ordinary skill in the art to which the present disclosure pertains by referencing the detailed description of the present disclosure given below.

According to an aspect of the present disclosure, there is provided a semiconductor memory device comprising a first data storage pattern on a substrate, a second data storage pattern spaced apart from the first data storage pattern in a first direction, a first bitline between the first and second data storage patterns, and extending in a second direction perpendicular to the first direction, a second bitline between the first and second data storage patterns, extending in the second direction, and spaced apart from the first bitline in the first direction, a wordline between the first and second bitlines, and extending in a third direction perpendicular to the first and second directions, a first active pattern between the first and second bitlines, and connected to the first data storage pattern, and a second active pattern between the first and second bitlines, and connected to the second data storage pattern.

According to an aspect of the present disclosure, there is provided a semiconductor memory device comprising first and second active patterns on a substrate and including first surfaces and second surfaces opposite to each other in a first direction, the first surfaces of the first and second active patterns facing the substrate, a first bitline extending in a second direction perpendicular to the first direction, and connected to the first surface of the first active pattern, a second bitline extending in the second direction and connected to the second surface of the second active pattern, a first wordline between the first and second bitlines and extending in a third direction perpendicular to both the first and second directions, a first data storage pattern connected to the second surface of the first active pattern, and a second data storage pattern connected to the first surface of the second active pattern.

According to an aspect of the present disclosure, there is provided a semiconductor memory device comprising first data storage patterns on a substrate, second data storage patterns spaced apart from the first data storage patterns in a first direction, first active patterns and second active patterns alternately disposed between the first data storage patterns and the second data storage patterns in a second direction perpendicular to the first direction, third active patterns and fourth active patterns alternately disposed in the second direction, wherein the third active patterns is spaced apart from the first active patterns in a third direction perpendicular to both the first and second directions, and the fourth active patterns are spaced apart from the second active patterns in the third direction, first bitlines between the first active patterns and the second data storage patterns, and between the third active patterns and the second data storage patterns, extending in the third direction, and connected to the first active patterns and the third active patterns, second bitlines between the second active patterns and the first data storage patterns, and between the fourth active patterns and the first data storage patterns, extending in the third direction, and connected to the second active patterns and the fourth active patterns, first wordlines adjacent to the first active patterns and the second active patterns in the third direction and extending in the second direction, and second wordlines adjacent to the third active patterns and the fourth active patterns in the third direction and extending in the second direction, wherein the first active patterns and the third active patterns are connected to the first data storage patterns, and the second and fourth active patterns are connected to the second data storage patterns.

It should be noted that the effects of the present disclosure are not limited to those described above, and other effects of the present disclosure will be apparent from the following description.

However, aspects, features and benefits of the present disclosure are not restricted to those set forth herein. The above and other aspects, features and benefits of the present disclosure will become more apparent to one of ordinary skill in the art to which the present disclosure pertains by referencing the detailed description of the present disclosure given below.

### BRIEF DESCRIPTION OF THE DRAWINGS

The above and other aspects and features of the present disclosure will become more apparent by describing in detail example embodiments thereof with reference to the attached drawings, wherein like reference numerals (when used) indicate corresponding elements throughout the several views, and in which:

FIG. 1 is a schematic layout diagram for explaining a semiconductor memory device according to some embodiments;

FIG. 2 is a schematic diagram for explaining the positional relationship between first data storage patterns, first contact patterns, and second bitlines of FIG. 1;

FIG. 3 is a schematic diagram for explaining the positional relationship between second data storage patterns, second contact patterns, and first bitlines of FIG. 1;

FIG. 4 is a schematic cross-sectional view taken along lines A-A and B-B of FIG. 1;

FIG. 5 is a schematic cross-sectional view taken along line C-C of FIG. 1;

FIG. 6 is a schematic cross-sectional view taken along lines D-D and E-E of FIG. 1;

FIG. 7 is an enlarged schematic cross-sectional view of region P of FIG. 4;

FIG. 8 is an enlarged schematic cross-sectional view of region Q of FIG. 4;

FIG. 9 is a schematic diagram for explaining a semiconductor memory device according to some embodiments;

FIG. 10 is a schematic diagram for explaining the semiconductor memory device according to some embodiments;

FIGS. 11 through 13 are schematic diagrams for explaining a semiconductor memory device according to some embodiments;

FIGS. 14 and 15 are schematic diagrams for explaining a semiconductor memory device according to some embodiments;

FIG. 16 is a schematic diagram for explaining a semiconductor memory device according to some embodiments; and

FIGS. 17 through 55 are schematic diagrams for explaining intermediate steps of a method of manufacturing a semiconductor memory device according to some embodiments.

### DETAILED DESCRIPTION

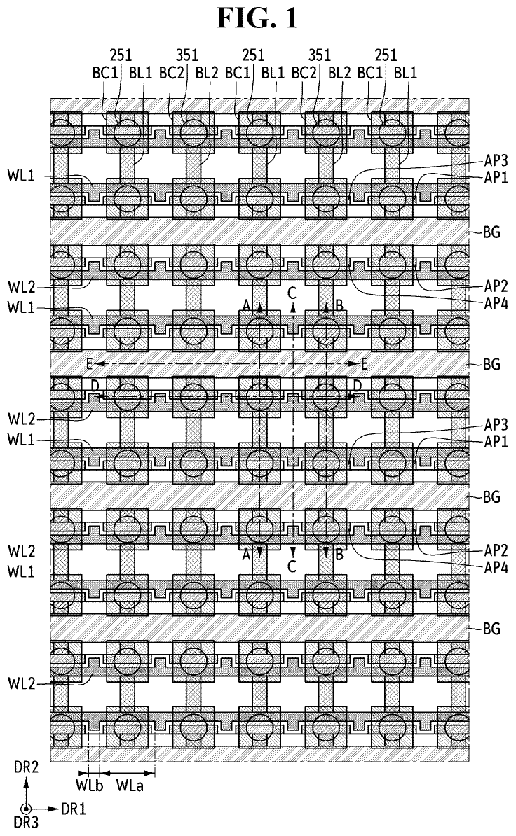

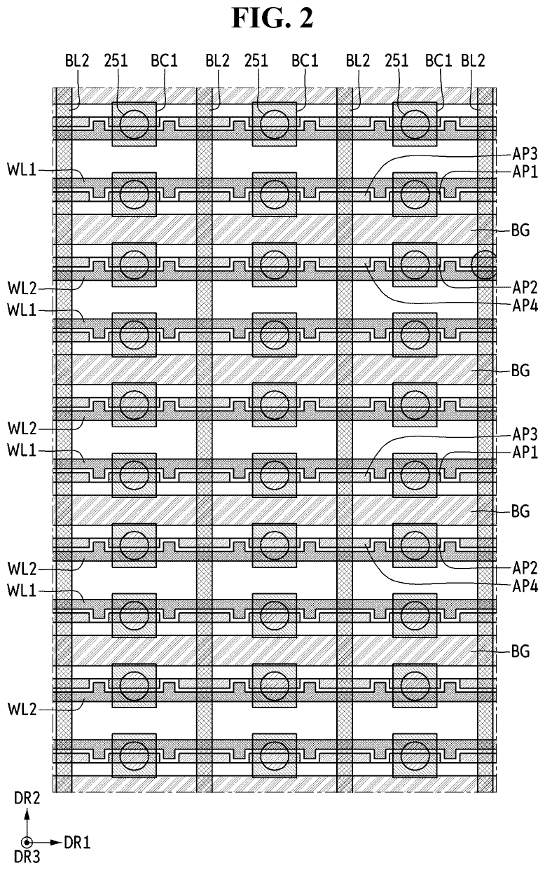

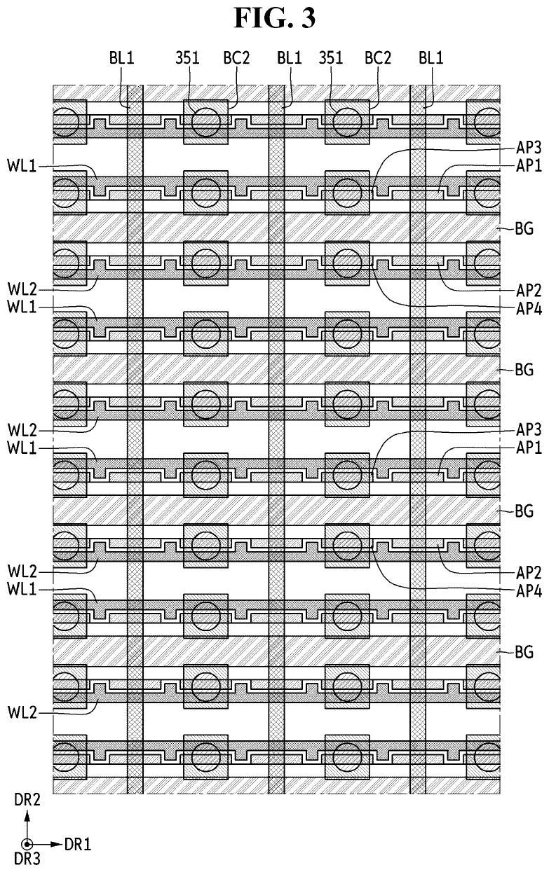

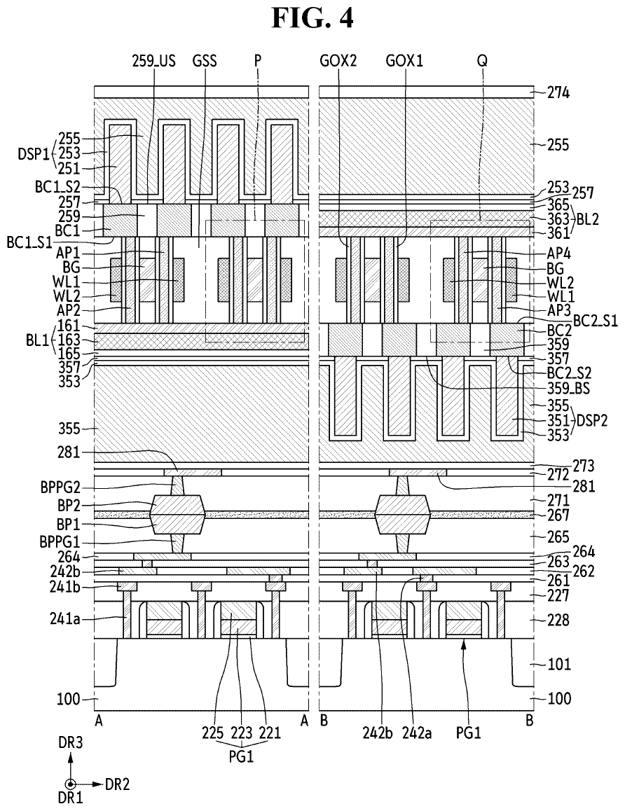

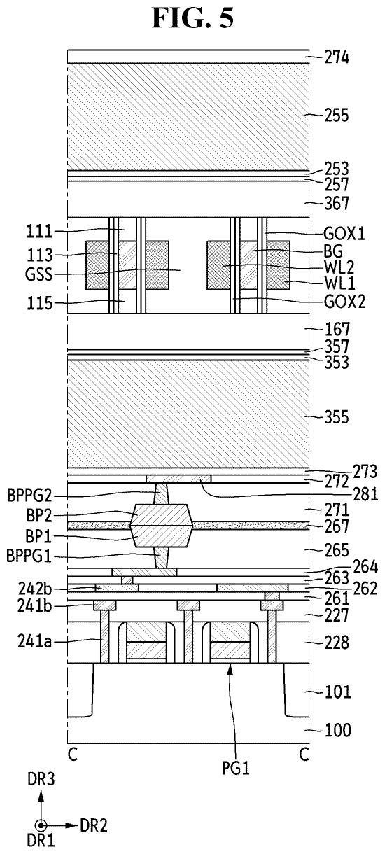

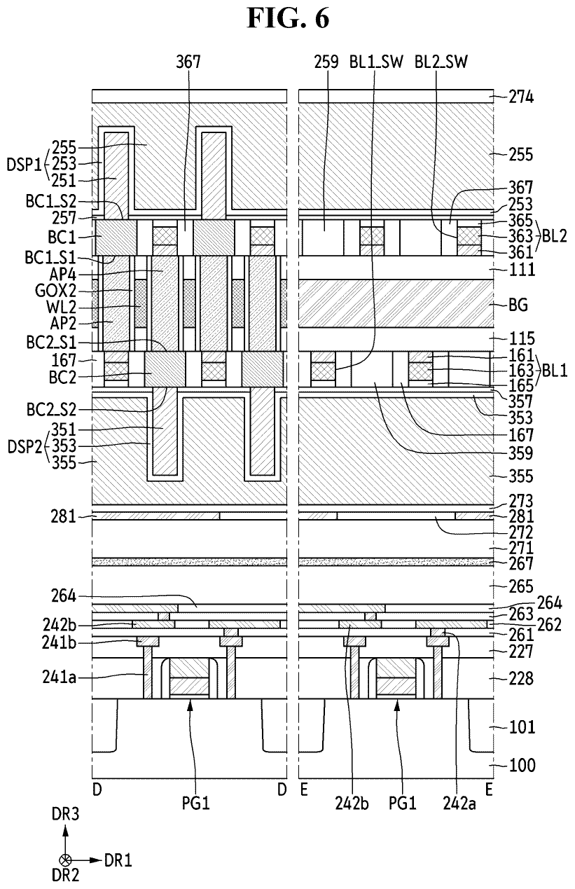

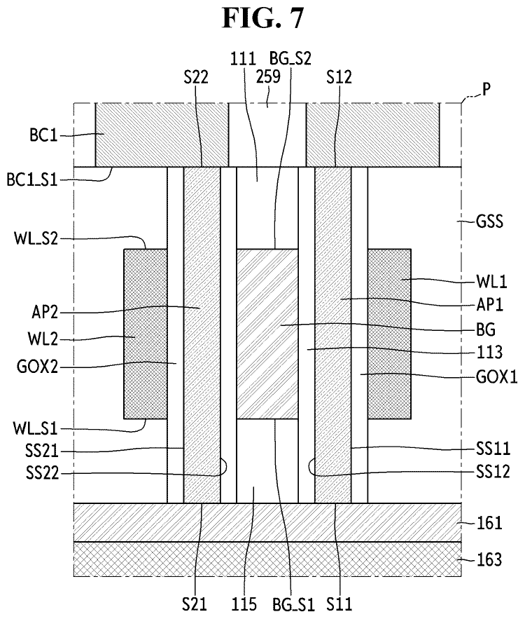

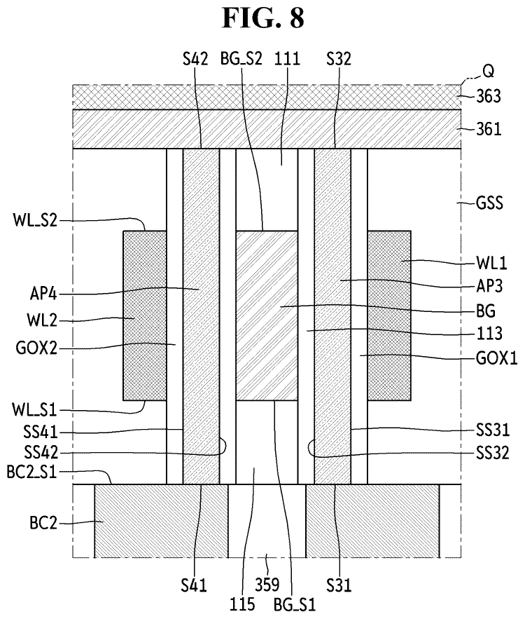

FIG. 1 is a schematic layout diagram for explaining a semiconductor memory device according to some embodiments. FIG. 2 is a schematic diagram for explaining the positional relationship between first data storage patterns, first contact patterns, and second bitlines of FIG. 1. FIG. 3 is a schematic diagram for explaining the positional relationship between second data storage patterns, second contact patterns, and first bitlines of FIG. 1. FIG. 4 is a schematic cross-sectional view taken along lines A-A and B-B of FIG. 1. FIG. 5 is a schematic cross-sectional view taken along line C-C of FIG. 1. FIG. 6 is a schematic cross-sectional view taken along lines D-D and E-E of FIG. 1. FIG. 7 is an enlarged schematic cross-sectional view of region P of FIG. 4. FIG. 8 is an enlarged schematic cross-sectional view of region Q of FIG. 4.

The semiconductor memory device according to some embodiments may include memory cells comprising vertical channel transistors (VCTs).

Referring to FIGS. 1 to 8 together, the semiconductor memory device according to some embodiments may include first bitlines BL1, second bitlines BL2, first wordlines WL1, second wordlines WL2, back gate electrodes BG, first active patterns AP1 through fourth active patterns AP4, first data storage patterns DSP1, second data storage patterns DSP2, and first peripheral gate structures PG1.

The semiconductor memory device includes a substrate 100, which may be a silicon (Si) substrate, or may include other materials, such as silicon-germanium (SiGe), indium antimonide, a lead telluride compound, indium arsenide, indium phosphide, gallium arsenide, or gallium antimonide, but the present disclosure is not limited thereto.

Although not explicitly illustrated, the substrate 100 may include a cell array region where the data storage patterns DSP1, DSP2 are disposed and a peripheral circuit region that is defined extending around the cell array region.

A first device isolation film 101 may be disposed within the substrate 100. The device isolation film 101 may define active areas within the substrate 100. The device isolation film 101 includes an insulating material.

The first peripheral gate structures PG1 may be disposed on the substrate 100. For example, the first peripheral gate structures PG1 may be disposed on an upper surface of the substrate 100. The first peripheral gate structures PG1 may be disposed across a cell array region and a peripheral circuit region. In other words, some of the first peripheral gate structures PG1 may be disposed in the cell array region of the substrate 100, and some of the first peripheral gate structures PG1 may be disposed in the peripheral circuit region of the substrate 100.

The first peripheral gate structures PG1 may be included in sensing transistors, transfer transistors, driving transistors, etc. For example, first peripheral gate structures PG1 included in sensing transistors may be disposed in the cell array region of the substrate 100, but the present disclosure is not limited thereto. The types of transistors included in the peripheral circuits disposed in the cell array region of the substrate 100 may vary depending on the design layout of the semiconductor memory device according to some embodiments.

The first peripheral gate structures PG1 may include a first peripheral gate insulating film 221, first peripheral lower conductive patterns 223, and first peripheral upper conductive patterns 225. The first peripheral gate insulating film 221 may include silicon oxide, silicon oxynitride, a high-k dielectric material having a dielectric constant higher than that of silicon oxide, or a combination thereof. The high-k dielectric material may include, for example, at least one of a metal oxide, a metal oxynitride, a metal silicon oxide, or a metal silicon oxynitride, but the present disclosure is not limited thereto.

The first peripheral lower conductive patterns 223 and the first peripheral upper conductive patterns 225 include a conductive material. For example, the first peripheral lower conductive patterns 223 and the first peripheral upper conductive patterns 225 may include at least one of a doped semiconductor material, a conductive metal nitride, a conductive metal silicon nitride, a metal carbonitride, a conductive metal silicide, a conductive metal oxide, a two-dimensional (2D) material, or a metal. The first peripheral gate structures PG1 are illustrated as including multiple conductive patterns, but the present disclosure is not limited thereto. The 2D material may be a metallic material and/or a semiconductor material. The 2D material may include a 2D allotrope or a 2D compound. For example, the 2D material may include at least one of graphene, molybdenum disulfide (MoS₂), molybdenum diselenide (MoSe₂), tungsten diselenide (WSe₂), or tungsten disulfide (WS₂), but the present disclosure is not limited thereto. In other words, the aforementioned 2D materials are merely examples, and the present disclosure is not limited thereto.

Although not illustrated, the first peripheral gate structures PG1 may further include first peripheral gate mask patterns disposed on the first peripheral upper conductive patterns 225. The first peripheral gate mask patterns are formed of an insulating material.

First and second peripheral lower insulating films 227 and 228 are disposed on the upper surface of the substrate 100. The first and second peripheral lower insulating films 227 and 228 include an insulating material.

First peripheral contact plugs 241a and first peripheral wiring lines 241b may be disposed within the first and second peripheral lower insulating films 227 and 228. The first peripheral contact plugs 241a and the first peripheral wiring lines 241b may be connected to first source/drain regions disposed on at least one side of the first peripheral gate structures PG1. The term “connected” (or “connecting,” or like terms, such as “contact” or “contacting”), as may be used herein, is intended to refer to a physical and/or electrical connection between two or more elements, and may include other intervening elements. As used herein, the term “and/or” includes any and all combinations of one or more of the associated listed items. Although not illustrated, the first peripheral contact plugs 241a and the first peripheral wiring lines 241b may be connected to conductive patterns (223 and 225) of the first peripheral gate structures PG1. For example, the first peripheral wiring lines 241b may be the closest wiring lines to the first peripheral gate structures PG1 in a third direction DR3 perpendicular to the upper surface of the substrate 100.

The first peripheral contact plugs 241a and the first peripheral wiring lines 241b are illustrated as being different films, but the present disclosure is not limited thereto. The boundaries between the first peripheral contact plugs 241a and the first peripheral wiring lines 241b may not be distinguishable. The first peripheral contact plugs 241a and the first peripheral wiring lines 241b include a conductive material.

A first peripheral upper insulating film 261, a second peripheral upper insulating film 262, a third peripheral upper insulating film 263, and a fourth peripheral upper insulating film 264 may be disposed on the first peripheral contact plugs 241a and the first peripheral wiring lines 241b. Each of the first, second, third, and fourth peripheral upper insulating films 261, 262, 263, and 264 includes an insulating material. As illustrated, a single insulating film may be disposed on the first peripheral contact plugs 241a and the first peripheral wiring lines 241b, but the present disclosure is not limited thereto.

First peripheral connection structures (242a and 242b) may be connected to the first peripheral wiring line 241b. The first peripheral connection structures (242a and 242b) may include first peripheral connection vias 242a and first peripheral connection wires 242b. The first peripheral connection vias 242a and the first peripheral connection wires 242b include a conductive material.

The first peripheral connection vias 242a and the first peripheral connection wires 242b are illustrated as being different films, but the present disclosure is not limited thereto. The first peripheral connection structures (242a and 242b) are illustrated as including multiple first peripheral connection wires 242b disposed on two different metal levels, but the present disclosure is not limited thereto. Alternatively, contrary to what is illustrated, the first peripheral connection structures (242a and 242b) may include first peripheral connection wires 242b disposed on a single metal level.

A fifth peripheral upper insulating film 265 may be disposed on the first peripheral connection structures (242a and 242b). The fifth peripheral upper insulating film 265 includes an insulating material.

Lower bonding pads BP1 may be disposed on the first peripheral gate structures PG1. The lower bonding pads BP1 may be electrically connected to the first peripheral connection structures (242a and 242b).

For example, at least one of the lower bonding pads BP1 may be connected to the first peripheral gate structures PG1. At least one other of the lower bonding pads BP1 may be connected to first source/drain regions disposed on at least one side of the first peripheral gate structures PG1.

Lower pad plugs BPPG1 may connect the lower bonding pads BP1 and the first peripheral connection wires 242b. The lower bonding pads BP1 and the lower pad plugs BPPG1 may be disposed within the fifth peripheral upper insulating film 265.

First, second, and third cell lower insulating films 271, 272, and 273 may be disposed on the fifth peri-upper insulating film 265. The first, second, and third cell lower insulating films 271, 272, and 273 may be disposed on the lower bonding pads BP1.

The second cell lower insulating film 272 may be disposed between the first cell lower insulating film 271 and the third cell lower insulating film 273. The first cell lower insulating film 271 may be disposed between the second cell lower insulating film 272 and the fifth peri-upper insulating film 265. The first, second, and third cell lower insulating films 271, 272, and 273 may include an insulating material.

Upper bonding pads BP2 may be disposed on the lower bonding pads BP1. The upper bonding pads BP2 may be disposed on the fifth peri-upper insulating film 265.

The upper bonding pads BP2 may be connected to the lower bonding pads BP1. The upper bonding pads BP2 may contact the lower bonding pads BP1.

First cell connection wires 281 may be disposed on the first upper bonding pads BP2. The first cell connection wires 281 may be disposed between the upper bonding pads BP2 and the second data storage patterns DSP2. Although not illustrated, the first cell connection wires 281 may be electrically connected to at least one of first bitlines BL1, second bitlines BL2, first wordlines WL1, or second wordlines WL2, which will be described later.

First cell connection wires 281 disposed on a single metal level are illustrated as being disposed between the upper bonding pads BP2 and the second data storage patterns DSP2, but the present disclosure is not limited thereto. Alternatively, first cell connection wires 281 disposed on different metal levels may be disposed between the upper bonding pads BP2 and the second data storage patterns DSP2.

Upper pad plugs BPPG2 may electrically connect the upper bonding pads BP2 and the first cell connection wires 281. The upper bonding pads BP2 may be connected to the first cell connection wires 281 through the upper pad plugs BPPG2.

The upper bonding pads BP2 and the upper pad plugs BPPG2 may be disposed within the first cell lower insulating film 271. The first cell connection wires 281 may be disposed within the second cell lower insulating film 272.

The upper pad plugs BPPG2 and the lower pad plugs BPPG1 may include a conductive material containing metal. The lower bonding pads BP1 and the upper bonding pads BP2 may include a conductive material containing metal. The first cell connection wires 281 may include a conductive material containing metal. The first cell connection wires 281 may include a conductive material containing metal.

The lower bonding pads BP1 and the upper bonding pads BP2 are illustrated as being single films, but the present disclosure is not limited thereto. The upper pad plugs BPPG2 and the lower pad plugs BPPG1 are illustrated as being single films, but the present disclosure is not limited thereto. The first cell connection wires 281 are illustrated as being single films, but the present disclosure is not limited thereto.

A bonding insulating film 267 may be disposed between the first cell lower insulating film 271 and the fifth peri-upper insulating film 265. The bonding insulating film 267 may be disposed along the extension lines of the interfaces between the lower bonding pads BP1 and the upper bonding pads BP2. The interfaces between the lower bonding pads BP1 and the upper bonding pads BP2 may correspond to the boundaries between the lower bonding pads BP1 and the upper bonding pads BP2.

For example, the bonding insulating film 267 may include silicon carbonitride. In another example, the bonding insulating film 267 may include silicon oxide.

At the interfaces between the lower bonding pads BP1 and the upper bonding pads BP2, a width of the lower bonding pads BP1, in a second direction DR2 parallel to the upper surface of the substrate, may be the same as the width of the upper bonding pads BP2 in the second direction DR2. Alternatively, contrary to what is illustrated, at the interfaces between the lower bonding pads BP1 and the upper bonding pads BP2, the width of the lower bonding pads BP1 in the second direction DR2 may differ from the width of the upper bonding pads BP2 in the second direction DR2.

At the interfaces between the lower bonding pads BP1 and the upper bonding pads BP2, the lower bonding pads BP1 may be aligned with the upper bonding pads BP2 in the third direction DR3. Alternatively, contrary to what is illustrated, at the interfaces between the lower bonding pads BP1 and the upper bonding pads BP2, the lower bonding pads BP1 may be misaligned with (i.e., offset from) the upper bonding pads BP2 in the third direction DR3.

The first data storage patterns DSP1 and the second data storage patterns DSP2 may be disposed on the substrate 100. The first data storage patterns DSP1 may be spaced apart from the second data storage patterns DSP2 in the third direction DR3. For example, the third direction DR3 may be a vertical direction perpendicular to the substrate 100.

For example, the first data storage patterns DSP1 and the second data storage patterns DSP2 may be disposed on the upper bonding pads BP2. The first peripheral gate structures PG1 may be disposed between the second data storage patterns DSP2 and the substrate 100. The second data storage patterns DSP2 may be disposed between the first data storage patterns DSP1 and the first peripheral gate structures PG1.

As illustrated in FIGS. 1 and 2, the first data storage patterns DSP1 may be arranged in a matrix form along a first direction DR1 and the second direction DR2. As illustrated in FIGS. 1 and 3, the second data storage patterns DSP2 may be arranged in a matrix form along the first and second directions DR1 and DR2.

The first and second directions DR1 and DR2 may each be perpendicular to the third direction DR3. The first and second directions DR1 and DR2 may be horizontal directions parallel to the substrate 100. For example, the first direction DR1 may be perpendicular to the second direction DR2.

In one example, the first data storage patterns DSP1 and the second data storage patterns DSP2 may be capacitors. The first data storage patterns DSP1 may include first storage electrodes 251 and a first capacitor dielectric film 253 interposed between the first storage electrodes 251 and a first plate electrode 255. The second data storage patterns DSP2 may include second storage electrodes 351 and a second capacitor dielectric film 353 interposed between the second storage electrode 351 and a second plate electrode 355. From a planar perspective (i.e., plan view), the first storage electrodes 251 and the second storage electrodes 351 may have various shapes such as, for example, circular, elliptical, rectangular, square, rhombic, or hexagonal.

The first storage electrodes 251, the second storage electrodes 351, the first plate electrode 255, and the second plate electrode 355 may include, for example, at least one of a conductive semiconductor material, a conductive metal nitride, a conductive metal silicon nitride, a metal carbonitride, a conductive metal silicide, a conductive metal oxide, or a metal. The first and second capacitor dielectric films 253 and 353 may include at least one of a ferroelectric material, an antiferroelectric material, or a paraelectric material. For example, the first and second capacitor dielectric films 253 and 353 may include one of a ferroelectric material, an antiferroelectric material, a paraelectric material, a combination of ferroelectric and antiferroelectric materials, a combination of ferroelectric and paraelectric materials, a combination of paraelectric and antiferroelectric materials, or a combination of ferroelectric, antiferroelectric, and paraelectric materials.

Alternatively, the first data storage patterns DSP1 and the second data storage patterns DSP2 may be variable resistance patterns that can switch between two resistance states based on an electric pulse applied to the respective memory elements. For example, the first data storage patterns DSP1 and the second data storage patterns DSP2 may include a phase-change material whose crystalline state changes according to the amount of current, a perovskite compound, a transition metal oxide, a magnetic material, a ferromagnetic material, or an antiferromagnetic material.

Alternatively, for example, either the first data storage patterns DSP1 or the second data storage patterns DSP2 may be capacitors, and the other data storage patterns may include variable resistance patterns that can switch between two resistance states based on the electric pulse applied to the respective memory elements. Yet alternatively, for example, the first data storage patterns DSP1 and the second data storage patterns DSP2 may include different types of variable resistance patterns.

A first cell upper insulating film 274 may be disposed on the first data storage patterns DSP1. The first cell upper insulating film 274 may cover the first plate electrode 255. The first cell upper insulating film 274 includes an insulating material. The term “cover” (or “covers,” or like terms), as may be used herein, is intended to broadly refer to an element, structure or layer that is on or over another element, structure or layer, either directly or with one or more other intervening elements, structures or layers therebetween.

The first active patterns AP1 and the second active patterns AP2 may be disposed between the first data storage patterns DSP1 and the second data storage patterns DSP2. The third active patterns AP3 and the fourth active patterns AP4 may be disposed between the first data storage patterns DSP1 and the second data storage patterns DSP2.

The first active patterns AP1 and the second active patterns AP2 may be alternately arranged along the second direction DR2. The first active patterns AP1 and the second active patterns AP2 may be spaced apart in the second direction DR2. For example, the first active patterns AP1 and the second active patterns AP2 may be aligned along the second direction DR2.

The third active patterns AP3 and the fourth active patterns AP4 may be alternately arranged along the second direction DR2. The third active patterns AP3 and the fourth active patterns AP4 may be spaced apart in the second direction DR2. For example, the third active patterns AP3 and the fourth active patterns AP4 may be aligned along the second direction DR2.

The first active patterns AP1 and the third active patterns AP3 may be alternately arranged along the first direction DR1. The first active patterns AP1 and the third active patterns AP3 may be spaced apart in the first direction DR1. For example, the first active patterns AP1 and the third active patterns AP3 may be aligned along the first direction DR1.

The second active patterns AP2 and the fourth active patterns AP4 may be alternately arranged along the first direction DR1. The second active patterns AP2 and the fourth active patterns AP4 may be spaced apart in the first direction DR1. For example, the second active patterns AP2 and the fourth active patterns AP4 may be aligned along the first direction DR1.

The first active patterns AP1, the second active patterns AP2, the third active patterns AP3, and the fourth active patterns AP4 may be arranged two-dimensionally along the first and second directions DR1 and DR2, which intersect each other.

The first active patterns AP1, the second active patterns AP2, the third active patterns AP3, and the fourth active patterns AP4 may be channel regions. For example, the first active patterns AP1, the second active patterns AP2, the third active patterns AP3, and the fourth active patterns AP4 may be formed of a monocrystalline semiconductor material. In one example, the first active patterns AP1, the second active patterns AP2, the third active patterns AP3, and the fourth active patterns AP4 may be formed of monocrystalline silicon (Si). The first active patterns AP1, the second active patterns AP2, the third active patterns AP3, and the fourth active patterns AP4 may be Si active patterns.

The first active patterns AP1, the second active patterns AP2, the third active patterns AP3, and the fourth active patterns AP4 may each have a length in the first direction DR1, a width in the second direction DR2, and a height in the third direction DR3. The first active patterns AP1, the second active patterns AP2, the third active patterns AP3, and the fourth active patterns AP4 may each have a substantially uniform width.

The widths of the first active patterns AP1, the second active patterns AP2, the third active patterns AP3, and the fourth active patterns AP4 may be several nanometers (nm) to several tens of nm. For example, the widths of the first active patterns AP1, the second active patterns AP2, the third active patterns AP3, and the fourth active patterns AP4 may be about 1 nm to 30 nm, more preferably about 1 nm to 10 nm, but the present disclosure is not limited thereto. The lengths of the first active patterns AP1 and the second active patterns AP2 may be greater than the line width of the first bitlines BL1. That is, the lengths of the first active patterns AP1 and the second active patterns AP2 may be greater than the width of the first bitline BL1 in the first direction DR1. The lengths of the third active patterns AP3 and the fourth active patterns AP4 may be greater than the line width of the second bitlines BL2.

In FIGS. 7 and 8, the first active patterns AP1 include first surfaces S11 and second surfaces S12 opposite to each other in the third direction DR3. The second active patterns AP2 include first surfaces S21 and second surfaces S22 opposite to each other in the third direction DR3. The third active patterns AP3 include first surfaces S31 and second surfaces S32 opposite to each other in the third direction DR3. The fourth active patterns AP4 include first surfaces S41 and second surfaces S42 opposite to each other in the third direction DR3. The first surfaces S11 of the first active patterns AP1, the first surfaces S21 of the second active patterns AP2, the first surfaces S31 of the third active patterns AP3, and the first surfaces S41 of the fourth active patterns AP4 may face the substrate 100.

The first active patterns AP1 include first sidewalls SS11 and second sidewalls SS12 opposite to each other in the second direction DR2. The second active patterns AP2 include first sidewalls SS21 and second sidewalls SS22 opposite to each other in the second direction DR2. The third active patterns AP3 include first sidewalls SS31 and second sidewalls SS32 opposite to each other in the second direction DR2. The fourth active patterns AP4 include first sidewalls SS41 and second sidewalls SS42 opposite to each other in the second direction DR2. The second sidewalls SS12 of the first active patterns AP1 may face the second sidewalls SS22 of the second active patterns AP2. The second sidewalls SS32 of the third active patterns AP3 may face the second sidewalls SS42 of the fourth active patterns AP4.

Although not illustrated, for example, the first active patterns AP1 and the second active patterns AP2 may include first dopant regions adjacent to the first bitline BL1 and second dopant regions adjacent to first contact patterns BC1. The first active patterns AP1 and the second active patterns AP2 may include first channel regions between the first dopant regions and the second dopant regions. The first dopant regions and the second dopant regions are doped regions within the first active patterns AP1 and the second active patterns AP2. Alternatively, the first active patterns AP1 and the second active patterns AP2 may not include either the first dopant regions or the second dopant regions. The third active patterns AP3 and the fourth active patterns AP4 may include third dopant regions adjacent to the second bitlines BL2 and fourth dopant regions adjacent to second contact patterns BC2. The third active patterns AP3 and the fourth active patterns AP4 may include second channel regions between the third dopant regions and the fourth dopant regions. Alternatively, the third active patterns AP3 and the fourth active patterns AP4 may not include either the third dopant regions or the fourth dopant regions.

During the operation of the semiconductor memory device according to some embodiments, the channel regions of the first active patterns AP1 through the fourth active patterns AP4 may be controlled by the first wordlines WL1, the second wordlines WL2, and the back gate electrodes BG. Since the first active patterns AP1 through the fourth active patterns AP4 are formed of a monocrystalline semiconductor material, the leakage current characteristics of the semiconductor memory device according to some embodiments may be improved.

The first bitlines BL1 and the second bitlines BL2 may be disposed between the first data storage patterns DSP1 and the second data storage patterns DSP2. The first bitlines BL1 may be disposed between the second data storage patterns DSP2 and the first active patterns AP1, and between the second data storage patterns DSP2 and the second active patterns AP2. The second bitlines BL2 may be disposed between the first data storage patterns DSP1 and the third active patterns AP3, and between the first data storage patterns DSP1 and the fourth active patterns AP4.

The first bitlines BL1 may extend in the second direction DR2. Adjacent first bitlines BL1 may be spaced apart in the first direction DR1. The second bitlines BL2 may extend in the second direction DR2. Adjacent second bitlines BL2 may be spaced apart in the first direction DR1.

The first active patterns AP1 through the fourth active patterns AP4 may be disposed between the first bitlines BL1 and the second bitlines BL2. The first bitlines BL1 and the second bitlines BL2 may be spaced apart in the third direction DR3, with the first active patterns AP1 through the fourth active patterns AP4 disposed therebetween. From a planar perspective, the first bitlines BL1 may be disposed between adjacent second bitlines BL2 in the first direction DR1. The first bitlines BL1 and the second bitlines BL2 may be alternately arranged along the first direction DR1.

Although not illustrated, the first bitlines BL1 and the second bitlines BL2 may extend from the cell array region to the peripheral circuit region. Portions of the first bitlines BL1 and portions of the second bitlines BL2 may be disposed in the peripheral circuit region.

The first bitlines BL1 may include first semiconductor patterns 161, first metal patterns 163, and first bitline mask patterns 165 that are sequentially stacked in the third direction DR3. The second bitlines BL2 may include second semiconductor patterns 361, second metal patterns 363, and second bitline mask patterns 365 that are sequentially stacked in the third direction DR3. Alternatively, contrary to what is illustrated, for example, the first bitlines BL1 may include one of the first semiconductor pattern 161 or the first metal pattern 163, and a second bitline BL2 may include either the second semiconductor patterns 361 or the second metal patterns 363. Yet alternatively, for example, the first bitlines BL1 may not include the first bitline mask patterns 165, and the second bitlines BL2 may not include the second bitline mask patterns 365.

The first bitlines BL1 and the second bitlines BL2 may include conductive bitlines. The conductive bitlines may include films formed of a conductive material in either the first bitlines BL1 or the second bitlines BL2. The conductive bitlines of the first bitlines BL1 may include the first semiconductor patterns 161 and the first metal patterns 163, and the conductive bitlines of the second bitlines BL2 may include the second semiconductor patterns 361 and the second metal patterns 363.

The first semiconductor patterns 161 and the second semiconductor patterns 361 may include a conductive semiconductor material. The conductive semiconductor material may be, for example, a semiconductor material doped with impurities. The first semiconductor patterns 161 and the second semiconductor patterns 361 may include at least one of polysilicon, polysilicon germanium, polycrystalline germanium, amorphous silicon, amorphous silicon germanium, or amorphous germanium.

The first metal patterns 163 and the second metal patterns 363 may include a conductive material containing metal. For example, the first metal patterns 163 and the second metal patterns 363 may include at least one of a conductive metal nitride, a conductive metal silicon nitride, a metal carbonitride, a conductive metal silicide, a conductive metal oxide, a 2D material, or a metal.

The first bitline mask patterns 165 and the second bitline mask patterns 365 may include an insulating material. The first bitline mask patterns 165 and the second bitline mask patterns 365 may include, for example, silicon nitride or silicon oxynitride, but the present disclosure is not limited thereto.

First bitline spacers 167 may be disposed on sidewalls BL1_SW of the first bitlines BL1. The first bitline spacers 167 may extend along the sidewalls BL1_SW of the first bitlines BL1 in the second direction DR2. Second bitline spacers 367 may be disposed on sidewalls BL2_SW of the second bitlines BL2. The second bitline spacers 367 may extend along the sidewalls BL2_SW of the second bitlines BL2 in the second direction DR2.

The first bitline spacers 167 and the second bitline spacers 367 may include an insulating material. The first bitline mask patterns 165 and the second bitline mask patterns 365 may include, for example, silicon nitride or silicon oxynitride, but the present disclosure is not limited thereto.

The first bitlines BL1 may be connected to the first active patterns AP1 and the second active patterns AP2. For example, the first bitlines BL1 may be electrically connected to the first active patterns AP1 and the second active patterns AP2. A single first bitline BL1 may be connected to first active patterns AP1 and second active patterns AP2 that are alternately arranged along the second direction DR2. The first active patterns AP1 and the second active patterns AP2 are not connected to the second bitlines BL2.

The first surfaces S11 of the first active patterns AP1 and the first surfaces S21 of the second active patterns AP2 may face the first bitlines BL1. The first surfaces S11 of the first active patterns AP1 and the first surfaces S21 of the second active patterns AP2 may be connected to the first bitlines BL1. For example, the first surfaces S11 of the first active patterns AP1 and the first surfaces S21 of the second active patterns AP2 may be connected to the first semiconductor patterns 161 of the first bitlines BL1. Alternatively, contrary to what is illustrated, if the first semiconductor patterns 161 are omitted, the first surfaces S11 of the first active patterns AP1 and the first surfaces S21 of the second active patterns AP2 may be connected to the first metal patterns 163.

The second bitlines BL2 may be connected to the third active patterns AP3 and the fourth active patterns AP4. For example, the second bitlines BL2 may be electrically connected to the third active patterns AP3 and the fourth active patterns AP4. A single second bitline BL2 may be connected to third active patterns AP3 and fourth active patterns AP4 that are alternately arranged along the second direction DR2. The third active patterns AP3 and the fourth active patterns AP4 are not connected to the first bitlines BL1.

The second surfaces S32 of the third active patterns AP3 and the second surfaces S42 of the fourth active patterns AP4 may face the second bitlines BL2. The second surfaces S32 of the third active patterns AP3 and the second surfaces S42 of the fourth active patterns AP4 may be connected to the second bitlines BL2. For example, the second surfaces S32 of the third active patterns AP3 and the second surfaces S42 of the fourth active patterns AP4 may be connected to the second semiconductor patterns 361 of the second bitlines BL2. Alternatively, contrary to what is illustrated, if the second semiconductor patterns 361 are omitted, the second surfaces S32 of the third active patterns AP3 and the second surfaces S42 of the fourth active patterns AP4 may be connected to the second metal patterns 363.

The first contact patterns BC1 may be disposed between the first data storage patterns DSP1 and the first active patterns AP1. The first contact patterns BC1 may be disposed between the first data storage patterns DSP1 and the second active patterns AP2. The first active patterns AP1 and the second active patterns AP2 may be disposed between the first contact patterns BC1 and the first bitlines BL1.

The first contact patterns BC1 may be connected to the first active patterns AP1. The first contact patterns BC1 may be connected to the second active patterns AP2. The first contact pattern BC1 may connect the first active patterns AP1 and the first data storage patterns DSP1.

The first contact patterns BC1 may connect the second active patterns AP2 and the first data storage patterns DSP1.

The second contact patterns BC2 may be disposed between the second data storage patterns DSP2 and the third active patterns AP3. The second contact patterns BC2 may be disposed between the second data storage patterns DSP2 and the fourth active patterns AP4. The third active patterns AP3 and the fourth active patterns AP4 may be disposed between the second contact patterns BC2 and the second bitlines BL2.

The second contact patterns BC2 may be connected to the third active patterns AP3. The second contact patterns BC2 may be connected to the fourth active patterns AP4. The second contact patterns BC2 may connect the third active patterns AP3 and the second data storage patterns DSP2. The second contact patterns BC2 may connect the fourth active patterns AP4 and the second data storage patterns DSP2.

The first active patterns AP1 and the second active patterns AP2 may be connected to the first data storage patterns DSP1. For example, the first active patterns AP1 and the second active patterns AP2 may be electrically connected to the first data storage patterns DSP1. The first active patterns AP1 and the second active patterns AP2 are not connected to the second data storage patterns DSP2.

The third active patterns AP3 and the fourth active patterns AP4 may be connected to the second data storage patterns DSP2. For example, the third active patterns AP3 and the fourth active patterns AP4 may be electrically connected to the second data storage patterns DSP2. The third active patterns AP3 and the fourth active patterns AP4 are not connected to the first data storage patterns DSP1.

The first contact patterns BC1 may be disposed between adjacent second bitlines BL2 in the first direction DR1. Between adjacent second bitlines BL2, the first contact pattern BC1 may be spaced apart in the second direction DR2. Between adjacent second bitlines BL2, the first contact patterns BC1 may be arranged in the second direction DR2. First contact patterns BC1 arranged in the second direction DR2 may overlap with the first bitlines BL1 in the third direction DR3. The first contact patterns BC1 may overlap with the second bitlines BL2 in the first direction DR1. As used herein, “an element A overlapping an element B in a direction X” (or similar language) means that there is at least one line that extends in the direction X and intersects both the elements A and B.

The second contact patterns BC2 may be disposed between adjacent first bitlines BL1 in the first direction DR1. Between adjacent first bitlines BL1, the second contact patterns BC2 may be spaced apart in the second direction DR2. Between adjacent first bitlines BL1, the second contact patterns BC2 may be arranged in the second direction DR2. Second contact patterns BC2 arranged in the second direction DR2 may overlap with the second bitlines BL2 in the third direction DR3. The second contact patterns BC2 may overlap with the first bitlines BL1 in the first direction DR1.

First fence patterns 259 may be disposed between the adjacent second bitlines BL2 in the first direction DR1. The first fence patterns 259 may be disposed between adjacent first contact patterns BC1 in the second direction DR2. The first fence patterns 259 may separate adjacent first contact patterns BC1.

The first fence patterns 259 may protrude (i.e., extend) from the second bitline spacers 367 in the first direction DR1. The first contact patterns BC1 may be surrounded by the first fence patterns 259 and the second bitline spacers 367; that is, the first fence patterns 259 and the second bitline spacers 367 may extend around the first contact patterns BC1. The term “surrounded” (or “surrounds,” or like terms), as may be used herein, is intended to broadly refer to an element, structure or layer that extends around, envelops, encircles, or encloses another element, structure or layer on all sides, although breaks or gaps may also be present. Thus, for example, a material layer having voids or gaps therein may still “surround” another layer which it encircles.

Second fence patterns 359 may be disposed between the adjacent first bitlines BL1 in the first direction DR1. The second fence patterns 359 may be disposed between adjacent second contact patterns BC2 in the second direction DR2. The second fence patterns 359 may separate adjacent second contact patterns BC2.

The second fence patterns 359 may protrude from the first bitline spacers 167 in the first direction DR1. The second contact patterns BC2 may be surrounded by the second fence patterns 359 and the first bitline spacers 167.

From a planar perspective, the first contact patterns BC1 may be rectangular. From a planar perspective, the second contact patterns BC2 may be rectangular.

The first contact patterns BC1 and the second contact patterns BC2 may include a conductive material. The first contact patterns BC1 and the second contact patterns BC2 may include, for example, at least one of doped polysilicon, a conductive metal nitride, a conductive metal silicon nitride, a metal carbonitride, a conductive metal silicide, a conductive metal oxide, a 2D material, or a metal. The first contact patterns BC1 and the second contact patterns BC2 are illustrated as being single films, but the present disclosure is not limited thereto.

Alternatively, contrary to what is illustrated, the first contact patterns BC1 and the second contact patterns BC2 may have a multi-conductive film structure consisting of multiple conductive films.

The first fence patterns 259 and the second fence patterns 359 may include an insulating material.

The first contact patterns BC1 may include first surfaces BC1_S1 and second surfaces BC1_S2 opposite to each other in the third direction DR3. The first surfaces BC1_S1 of the first contact patterns BC1 may be connected to the first active patterns AP1 or the second active patterns AP2. The second surfaces BC1_S2 of the first contact patterns BC1 may be connected to the first data storage patterns DSP1. For example, the second surfaces BC1_S2 of the first contact patterns BC1 may be connected to the first storage electrodes 251.

The second surfaces S12 of the first active patterns AP1 and the second surfaces S22 of the second active patterns AP2 may face the first contact patterns BC1. The second surfaces S12 of the first active patterns AP1 and the second surfaces S22 of the second active patterns AP2 may be connected to the first contact patterns BC1. Since the first contact patterns BC1 are connected to the first data storage patterns DSP1, the first data storage patterns DSP1 may be connected to the second surfaces S12 of the first active patterns AP1 or the second surfaces S22 of the second active patterns AP2.

The second contact patterns BC2 may include first surfaces BC2_S1 and second surfaces BC2_S2 opposite to each other in the third direction DR3. The first surfaces BC2_S1 of the second contact patterns BC2 may be connected to the third active patterns AP3 or the fourth active patterns AP4. The second surfaces BC2_S2 of the second contact patterns BC2 may be connected to the second data storage patterns DSP2. For example, the second surfaces BC2_S2 of the second contact patterns BC2 may be connected to the second storage electrodes 351.

The first surfaces S31 of the third active patterns AP3 and the first surfaces S41 of the fourth active patterns AP4 may face the second contact patterns BC2. The first surfaces S31 of the third active patterns AP3 and the first surfaces S41 of the fourth active patterns AP4 may be connected to the second contact patterns BC2. Since the second contact patterns BC2 are connected to the second data storage patterns DSP2, the second data storage patterns DSP2 may be connected to the first surfaces S31 of the third active patterns AP3 or the first surfaces S41 of the fourth active patterns AP4.

The first fence patterns 259 may include upper surfaces 259_US that face the first data storage patterns DSP1. The second fence patterns 359 may include lower surfaces 359_BS that face the second data storage patterns DSP2. The upper surface 259_US of the first fence patterns 259 may be at the same plane as the second surfaces BC1_S2 of the first contact patterns BC1.

The lower surfaces 359_BS of the second fence patterns 359 may be at the same plane as the second surfaces BC2_S2 of the second contact patterns BC2.

A first etching stop film 257 may be disposed between the first contact patterns BC1 and the first data storage patterns DSP1, and between the second bitlines BL2 and the first data storage patterns DSP1. A second etching stop film 357 may be disposed between the second contact patterns BC2 and the second data storage patterns DSP2, and between the first bitlines BL1 and the second data storage patterns DSP2.

The first storage electrodes 251 may penetrate (i.e., extend in) the first etching stop film 257. The second storage electrodes 351 may penetrate the second etching stop film 357. The first and second etching stop films 257 and 357 may be formed of an insulating material.

As the contact patterns (BC1 and BC2) are disposed between adjacent bitlines (BL1 and BL2) in the first direction DR1, coupling between the adjacent bitlines (BL1 and BL2) in the first direction DR1 can be reduced. Accordingly, the performance and reliability of the semiconductor memory device according to some embodiments can be improved.

The back gate electrodes BG may be disposed between the first bitlines BL1 and the second bitlines BL2. The back gate electrodes BG may be spaced apart from one another in the second direction DR2. The back gate electrodes BG may be spaced at regular intervals. The back gate electrodes BG may extend across the first bitlines BL1 and the second bitlines BL2 in the first direction DR1.

The back gate electrodes BG may be disposed between pairs of adjacent first and second active patterns AP1 and AP2 in the second direction DR2. The back gate electrodes BG may be disposed between pairs of adjacent third and fourth active patterns AP3 and AP4 in the second direction DR2. In other words, the first active patterns AP1 and the third active patterns AP3 may be disposed on first sides of the respective back gate electrodes BG, and the second active patterns AP2 and the fourth active patterns AP4 may be disposed on second sides of the respective back gate electrodes BG. The height of the back gate electrodes BG in the third direction DR3 may be less than the height of each of the first active patterns AP1 through the fourth active patterns AP4 in the third direction DR3.

The back gate electrodes BG may be disposed between the second sidewalls SS12 of the first active patterns AP1 and the second sidewalls SS22 of the second active patterns AP2. The back gate electrodes BG may be disposed between the second sidewalls SS32 of the third active patterns AP3 and the second sidewalls SS42 of the fourth active patterns AP4. The back gate electrodes BG may be disposed on the second sidewalls SS12 of the first active patterns AP1, the second sidewalls SS22 of the second active patterns AP2, the second sidewalls SS32 of the third active patterns AP3, and the second sidewalls SS42 of the fourth active patterns AP4.

The first active patterns AP1 and the third active patterns AP3 may be disposed between the first wordlines WL1 and the back gate electrodes BG adjacent in the second direction DR2. The second active patterns AP2 and the fourth active patterns AP4 may be disposed between the second wordlines WL2 and the back gate electrodes BG adjacent in the second direction DR2. A pair of first and second wordlines WL1 and WL2 may be disposed between a pair of adjacent back gate electrodes BG in the second direction DR2.

The back gate electrodes BG may include first surfaces BG_S1 and second surfaces BG_S2 opposite to each other in the third direction DR3. The first surfaces BG_S1 of the back gate electrodes BG may face the first bitlines BL1. The second surfaces BG_S2 of the back gate electrodes BG may face the second bitlines BL2.

The back gate electrodes BG may include a conductive material, such as, for example, at least one of a conductive semiconductor material, a conductive metal nitride, a conductive metal silicon nitride, a metal carbonitride, a conductive metal silicide, a conductive metal oxide, a 2D material, or a metal.

During the operation of the semiconductor memory device according to some embodiments, a voltage may be applied to the back gate electrodes BG, allowing the threshold voltage of the VCTs to be adjusted. By adjusting the threshold voltage of the VCTs, the deterioration of leakage current characteristics can be prevented or at least reduced.

Back gate isolation patterns 111 and back gate capping patterns 115 may be disposed between pairs of adjacent first and second active patterns AP1 and AP2 in the second direction DR2. The back gate isolation patterns 111 and the back gate capping patterns 115 may be disposed between pairs of adjacent third and fourth active patterns AP3 and AP4 in the second direction DR2. The back gate isolation patterns 111 and the back gate capping patterns 115 may extend parallel to the back gate electrodes BG in the first direction DR1.

The back gate isolation patterns 111 may be disposed on the respective second surfaces BG_S2 of the back gate electrodes BG. The back gate capping patterns 115 may be disposed on the respective first surfaces BG_S1 of the back gate electrodes BG.

The back gate isolation patterns 111 and the back gate capping patterns 115 may be formed of an insulating material. For example, the back gate isolation patterns 111 and the back gate capping patterns 115 may include silicon oxide, silicon oxynitride, or silicon nitride, but the present disclosure is not limited thereto.

Back gate insulating patterns 113 may be disposed between the back gate electrodes BG and the first active patterns AP1, and between the back gate electrodes BG and the second active patterns AP2 in the second direction DR2. The back gate insulating patterns 113 may also be disposed between the back gate electrodes BG and the third active patterns AP3, and between the back gate electrodes BG and the fourth active patterns AP4 in the second direction DR2.

The back gate insulating patterns 113 may be disposed between the back gate isolation patterns 111 and the first active patterns AP1, and between the back gate isolation patterns 111 and the second active patterns AP2 in the second direction DR2. The back gate insulating patterns 113 may be disposed between the back gate isolation patterns 111 and the third active patterns AP3, and between the back gate isolation patterns 111 and the fourth active patterns AP4 in the second direction DR2. The back gate insulating patterns 113 may extend in the third direction DR3 on the second sidewalls SS12 of the first active patterns AP1, on the second sidewalls SS22 of the second active patterns AP2, on the second sidewalls SS12 of the second active patterns AP2, on the second sidewalls SS32 of the third active patterns AP3, and on the second sidewalls SS42 of the fourth active patterns AP4.

The back gate insulating patterns 113 may be formed of an insulating material. The back gate insulating patterns 113 may include, for example, silicon oxide films, silicon oxynitride films, high-k dielectric films with a dielectric constant higher than that of silicon oxide, or a combination thereof.

The first wordlines WL1 and the second wordlines WL2 may be disposed between the first bitlines BL1 and the second bitlines BL2. The first wordlines WL1 and the second wordlines WL2 may extend in the first direction DR1. The first wordlines WL1 and the second wordlines WL2 may be alternately arranged in the second direction DR2.

The first wordlines WL1 may be adjacent to the first active patterns AP1 and the third active patterns AP3. The first wordlines WL1 may be disposed on the first sidewalls SS11 of the first active patterns AP1 and the first sidewalls SS31 of the third active patterns AP3. The second wordlines WL2 may be adjacent to the second active patterns AP2 and the fourth active patterns AP4. The second wordlines WL2 may be disposed on the first sidewalls SS21 of the second active patterns AP2 and the first sidewalls SS41 of the fourth active patterns AP4.

The first wordlines WL1 may not be disposed on the second sidewalls SS12 of the first active patterns AP1 or the second sidewalls SS32 of the third active patterns AP3. The second wordlines WL2 may not be disposed on the second sidewalls SS22 of the second active patterns AP2 or the second sidewalls SS42 of the fourth active patterns AP4.

The first active patterns AP1 and the second active patterns AP2 may be disposed between pairs of adjacent first and second wordlines WL1 and WL2 in the second direction DR2. In other words, pairs of adjacent third and fourth active patterns AP3 and AP4 in the second direction DR2 may be disposed between pairs of adjacent first and second wordlines WL1 and WL2 in the second direction DR2.

The first wordlines WL1 and the second wordlines WL2 may be spaced apart from the first bitlines BL1 and the second bitlines BL2 in the third direction DR3. The first wordlines WL1 and the second wordlines WL2 may be spaced apart from the first contact patterns BC1 and the second contact patterns BC2 in the third direction DR3. The first wordlines WL1 and the second wordlines WL2 may be positioned between the first bitlines BL1 and the first contact patterns BC1, and between the second bitlines BL2 and the second contact patterns BC2.

The first wordlines WL1 and the second wordlines WL2 may each have a width in the second direction DR2. For example, the first wordlines WL1 and the second wordlines WL2 may include first portions WLa and second portions WLb, as shown in FIG. 1. The width of the first portions WLa in the second direction DR2 may be smaller than the width of the second portions WLb in the second direction DR2. In one example, the first portions WLa of the wordlines (WL1 and WL2) may be disposed on the bitlines (BL1 and BL2). The second portions WLb of the wordlines (WL1 and WL2) may be disposed between pairs of adjacent first and third active patterns AP1 and AP3 in the first direction DR1, or between pairs of adjacent second and fourth active patterns AP2 and AP4 in the first direction DR1.

The first wordlines WL1 and the second wordlines WL2 may include first portions WLa and second portions WLb that are alternately arranged along the first direction DR1. In the first wordlines WL1, the first active patterns AP1 and the third active patterns AP3 may be disposed between the second portions WLb of adjacent wordlines (WL1 and WL2) in the first direction DR1. In the second wordlines WL2, the second active patterns AP2 and the fourth active patterns AP4 may be disposed between the second portions WLb of the adjacent wordlines (WL1 and WL2) in the first direction DR1.

Each of the first wordlines WL1 and the second wordlines WL2 may include a first surface WL_S1 and a second surface WL_S2 opposite to each other in the third direction DR3. The respective first surfaces WL_S1 of the first wordlines WL1 and the respective first surfaces WL_S1 of the second wordlines WL2 may face the first bitlines BL1. The respective second surfaces WL_S2 of the first wordlines WL1 and the respective second surfaces WL_S2 of the second wordlines WL2 may face the second bitlines BL2.

For example, the height of the first wordlines WL1 in the third direction DR3 may be equal to the height of the back gate electrodes BG in the third direction DR3. In another example, the height of the first wordlines WL1 in the third direction DR3 may be greater than the height of the back gate electrodes BG in the third direction DR3. In yet another example, the height of the first wordlines WL1 in the third direction DR3 may be less than the height of the back gate electrodes BG in the third direction DR3.

For example, the upper surfaces of the first bitlines BL1 may be the surfaces connected to the first surfaces S11 of the first active patterns AP1 and the first surfaces S21 of the second active patterns AP2. For example, relative to the upper surfaces of the first bitlines BL1 as a reference, the height of the first surfaces WL_S1 of the first wordlines WL1 may be equal to the height of the first surfaces BG_S1 of the back gate electrodes BG in the third direction DR3. In another example, the first surfaces WL_S1 of the first wordlines WL1 may be higher than the first surfaces BG_S1 of the back gate electrodes BG in the third direction DR3, relative to the upper surfaces of the first bitlines BL1. In yet another example, the first surfaces WL_S1 of the first wordlines WL1 may be lower than the first surfaces BG_S1 of the back gate electrodes BG in the third direction DR3, relative to the upper surfaces of the first bitlines BL1.

Additionally, for example, relative to the upper surfaces of the first bitlines BL1 as a reference, the height of the second surfaces WL_S2 of the first wordlines WL1 may be equal to the height of the second surfaces BG_S2 of the back gate electrodes BG in the third direction DR3. In another example, the second surfaces WL_S2 of the first wordlines WL1 may be higher than the second surfaces BG_S2 of the back gate electrodes BG in the third direction DR3, relative to the upper surfaces of the first bitlines BL1. In yet another example, the second surfaces WL_S2 of the first wordlines WL1 may be lower than the second surfaces BG_S2 of the back gate electrodes BG in the third direction DR3, relative to the upper surfaces of the first bitlines BL1.

Each of the first surfaces WL_S1 of the first wordlines WL1 and the first surfaces WL_S1 of the second wordlines WL2 may be planar, but the present disclosure is not limited thereto. Each of the second surfaces WL_S2 of the first wordlines WL1 and the second surfaces WL_S2 of the second wordlines WL2 may be planar, but the present disclosure is not limited thereto. Each of the first surfaces BG_S1 and the second surfaces BG_S2 of the back gate electrodes BG are illustrated as being planar, but the present disclosure is not limited thereto.

The first wordlines WL1 and the second wordlines WL2 may include a conductive material. For example, the first wordlines WL1 and the second wordlines WL2 may include at least one of a conductive semiconductor material, a conductive metal nitride, a conductive metal silicon nitride, a metal carbonitride, a conductive metal silicide, a 2D material, or a metal.

First gate insulating patterns GOX1 may be disposed between the first wordlines WL1 and the first active patterns AP1, and between the first wordlines WL1 and the third active patterns AP3. The first gate insulating patterns GOX1 may extend along the first sidewalls SS11 of the first active patterns AP1 and the first sidewalls SS31 of the third active patterns AP3. The first gate insulating patterns GOX1 may extend in the first direction DR1 parallel to the first wordlines WL1.

Second gate insulating patterns GOX2 may be disposed between the second wordlines WL2 and the second active patterns AP2, and between the second wordlines WL2 and the fourth active patterns AP4. The second gate insulating patterns GOX2 may extend along the first sidewalls SS21 of the second active patterns AP2 and the first sidewalls SS41 of the fourth active patterns AP4. The second gate insulating patterns GOX2 may extend in the first direction DR1 parallel to the second wordlines WL2.

The first gate insulating patterns GOX1 and the second gate insulating patterns GOX2 may include silicon oxide, silicon oxynitride, a high-k dielectric material with a dielectric constant higher than silicon oxide, or a combination thereof. The high-k dielectric material may include, for example, at least one of a metal oxide, a metal oxynitride, a metal silicon oxide, or a metal silicon oxynitride, but the present disclosure is not limited thereto.

Gate separation patterns GSS may be disposed between the first bitlines BL1 and the second bitlines BL2. The gate separation patterns GSS may be disposed between the pairs of adjacent first and second wordlines WL1 and WL2 in the second direction DR2. The first wordlines WL1 and the second wordlines WL2 may be separated by the gate separation patterns GSS. The gate separation patterns GSS may extend in the first direction DR1 between the first wordlines WL1 and the second wordlines WL2.

The first wordlines WL1 may be disposed between the gate separation patterns GSS and the first active patterns AP1, and between the gate separation patterns GSS and the third active patterns AP3. The second wordlines WL2 may be disposed between the gate separation patterns GSS and the second active patterns AP2, and between the gate separation patterns GSS and the fourth active patterns AP4.

The gate separation patterns GSS may be formed of an insulating material. The gate separation patterns GSS are illustrated as being single films, but the present disclosure is not limited thereto. Alternatively, contrary to what is illustrated, the gate separation patterns GSS may include multiple insulating films.

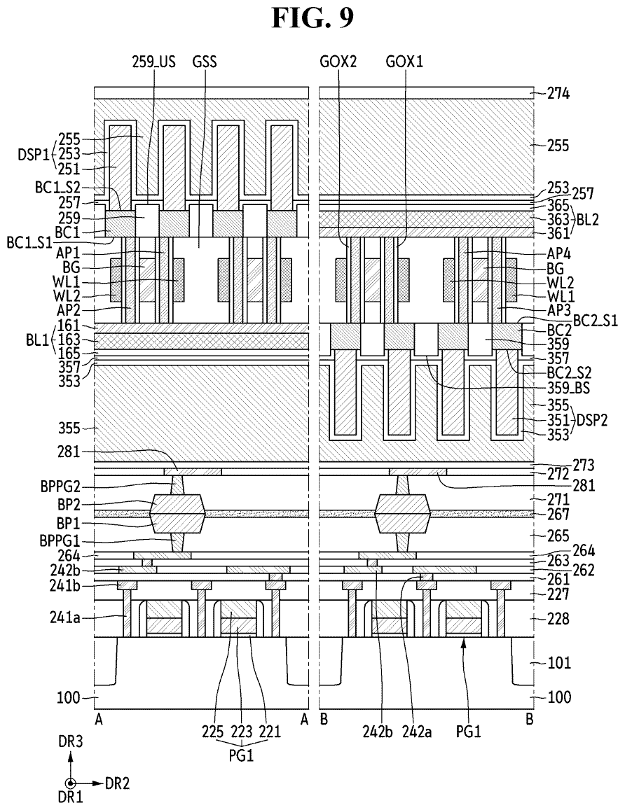

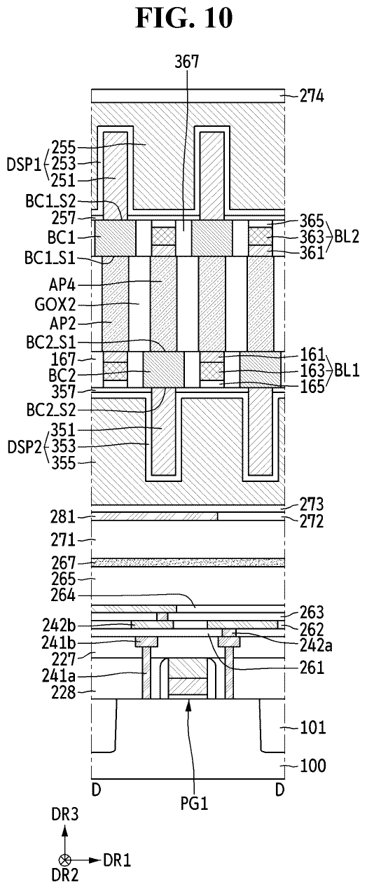

FIG. 9 is a schematic diagram for explaining a semiconductor memory device according to some embodiments. FIG. 10 is a schematic diagram for explaining the semiconductor memory device according to some embodiments. For convenience, the embodiment of FIGS. 9 and 10 will hereinafter be described, focusing mainly on the differences from what has been described with reference to FIGS. 1 through 8.

For reference, FIG. 9 is a schematic cross-sectional view taken along lines A-A and B-B of FIG. 1, and FIG. 10 is a schematic cross-sectional view taken along line D-D of FIG. 1.

Referring to FIG. 9, relative to first surfaces BC1_S1 of first contact patterns BC1, upper surfaces 259_US of first fence patterns 259 may be higher than second surfaces BC1_S2 of first contact patterns BC1 in the third direction DFR3.

The upper surfaces 259_US of the first fence patterns 259 may protrude in the third direction DR3 toward first data storage patterns DSP1 relative to the second surfaces BC1_S2 of the first contact patterns BC1.

Relative to first surfaces BC2_S1 of second contact patterns BC2, lower surfaces 359_BS of second fence patterns 395 may be higher than or lower than second surfaces BC2_S2 of the second contact patterns BC2 in the third direction DFR3. The lower surfaces 359_BS of the second fence patterns 395 may protrude in the third direction DFR3 toward second data storage patterns DSP2 relative to the second surfaces BC2_S2 of the second contact patterns BC2.

Referring to FIGS. 1 and 10, the width of first portions WLa of wordlines (WL1 and WL2) in a second direction DR2 may be equal to the width of second portions WLb of the wordlines (WL1 and WL2) in the second direction DR2.

Second gate insulating patterns GOX2 may fill the spaces between pairs of adjacent second and fourth active patterns AP2 and AP4 in a first direction DR1. The term “fill” (or “fills,” or like terms) is intended to refer to either completely filling a defined space (e.g., the space between adjacent second and fourth active patterns AP2 and AP4) or partially filling the defined space; that is, the defined space need not be entirely filled but may, for example, be partially filled or have voids or other spaces throughout. Although not explicitly illustrated, first gate insulating patterns GOX1 (of FIGS. 4 and 5) may similarly fill the spaces between pairs of adjacent first and third active patterns AP1 and AP3 in the first direction DR1.

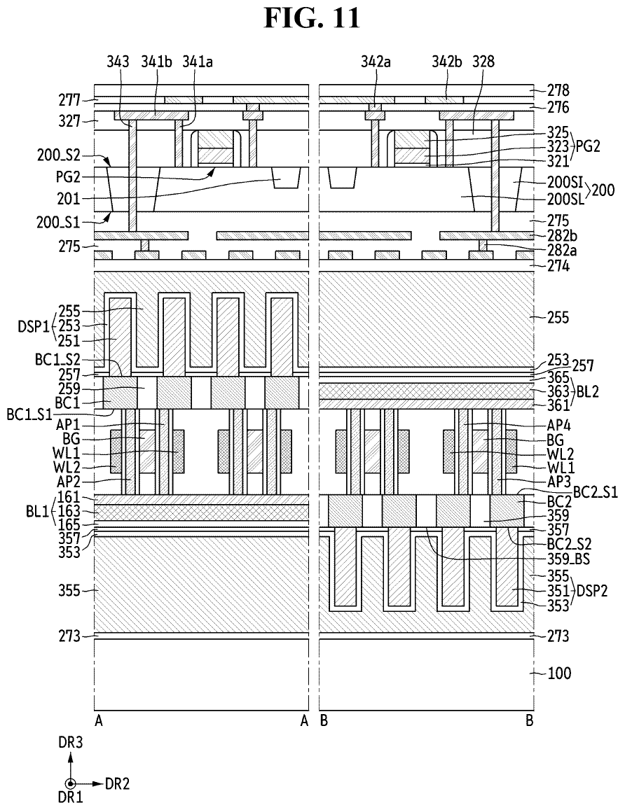

FIGS. 11 through 13 are schematic diagrams for explaining a semiconductor memory device according to some embodiments. For convenience, the embodiment of FIGS. 11 through 13 will hereinafter be described, focusing mainly on the differences from what has been described with reference to FIGS. 1 through 8.

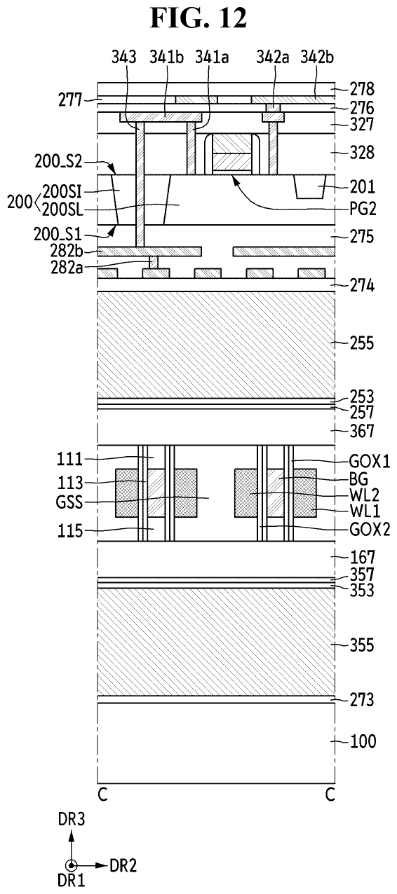

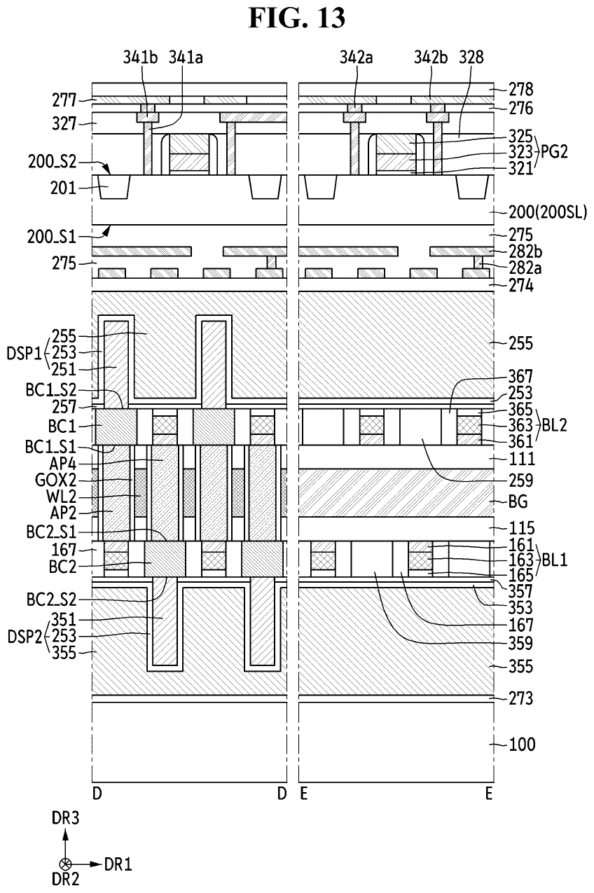

For reference, FIG. 11 is a schematic cross-sectional view taken along lines A-A and B- B of FIG. 1, FIG. 12 is a schematic cross-sectional view taken along line C-C of FIG. 1, and FIG. 13 is a schematic cross-sectional view taken along lines D-D and E-E of FIG. 1.

Referring to FIGS. 11 through 13, the semiconductor memory devices according to some embodiments may further include a peripheral active substrate 200, second peripheral gate structures PG2, and peripheral connection through plugs 343.

First peripheral gate structures PG1, lower bonding pads BP1, and upper bonding pads BP2 (see FIGS. 4-6) may not be disposed between the second data storage patterns DSP2 and a substrate 100.

A second cell upper insulating film 275 may be disposed on a first cell upper insulating film 274. The second cell upper insulating film 275 may include an insulating material.

Second cell connection vias 282a and second cell connection wires 282b may be disposed on the first cell upper insulating film 274. The second cell connection vias 282a and the second cell connection wires 282b may be disposed on the second cell upper insulating film 275.

Multiple second cell connection wires 282b disposed at different metal levels are illustrated as being within the second cell upper insulating film 275, but the present disclosure is not limited thereto.

Although not illustrated, the second cell connection wires 282b may be electrically connected to at least one of first bitlines BL1, second bitlines BL2, first wordlines WL1, or second wordlines WL2.

The second cell connection vias 282a and the second cell connection wires 282b may include a conductive material. The second cell connection vias 282a and second cell connection wires 282b are illustrated as being different films, but the present disclosure is not limited thereto.

The peripheral active substrate 200 may be disposed on the second cell connection wires 282b. The peripheral active substrate 200 may be spaced apart from the substrate 100 in the third direction DR3. The second cell connection vias 282a and the second cell connection wires 282b may be between the substrate 100 and the peripheral active substrate 200.

The peripheral active substrate 200 may include a peripheral semiconductor film 200SL and peripheral semiconductor isolation films 200SI. For example, the peripheral active substrate 200 may include a plurality of peripheral semiconductor isolation films 200SI.

The peripheral semiconductor film 200SL may include a semiconductor material. For example, the peripheral semiconductor film 200SL may include at least one of silicon, silicon germanium, indium antimonide, a lead telluride compound, indium arsenide, indium phosphide, gallium arsenide, or gallium antimonide, but the present disclosure is not limited thereto. The peripheral semiconductor film 200SL will hereinafter be described as being a silicon film comprising silicon.

The peripheral semiconductor isolation films 200SI may include an insulating material.

The peripheral semiconductor isolation films 200SI are illustrated as being single films, but the present disclosure is not limited thereto.

The peripheral active substrate 200 may include a first surface 200_S1 and a second surface 200_S2 opposite to each other in the third direction DR3. The first surfaces 200_S1 of the peripheral active substrate 200 may face the substrate 100 and the second cell connection wires 282b.

The first surface 200_S1 and the second surface 200_S2 of the peripheral active substrate 200 may include the peripheral semiconductor film 200SL and the peripheral semiconductor isolation films 200SI, respectively. In other words, the first surface 200_S1 and the second surface 200_S2 of the peripheral active substrate 200 may be defined by the peripheral semiconductor film 200SL and the peripheral semiconductor isolation films 200SI, respectively.

Second element isolation films 201 may be disposed within the peripheral semiconductor film 200SL. The second element isolation films 201 may be formed on the second surface 200_S2 of the peripheral active substrate 200. The second element isolation films 201 may not extend in the third direction DR3 to the first surface 200_S1 of the peripheral active substrate 200. The thickness of the second element isolation films 201 in the third direction DR3 may be less than the thickness of the peripheral semiconductor isolation films 200SI in the third direction DR3. The second element isolation films 201 may include an insulating material.

The second peripheral gate structures PG2 may be disposed on the peripheral semiconductor film 200SL. The second peripheral gate structures PG2 may be disposed on the second surface 200_S2 of the peripheral active substrate 200.

The second peripheral gate structures PG2 may include a second peripheral gate insulating film 321, second peripheral lower conductive patterns 323, and second peripheral upper conductive patterns 325. The second peripheral gate insulating film 321 may include silicon oxide, silicon oxynitride, a high-k dielectric material with a dielectric constant higher than that of silicon oxide, or a combination thereof. The second peripheral lower conductive patterns 323 and the second peripheral upper conductive patterns 325 may include at least one of a doped semiconductor material, a conductive metal nitride, a conductive metal silicon nitride, a metal carbonitride, a conductive metal silicide, a conductive metal oxide, a 2D material, or a metal. The second peripheral gate structures PG2 are illustrated as including multiple conductive patterns, but the present disclosure is not limited thereto.

A third peripheral lower insulating film 327 and a fourth peripheral lower insulating film 328 may be disposed on the second surface 200_S2 of the peripheral active substrate 200. The third and fourth peripheral lower insulating films 327 and 328 may include an insulating material.

Second peripheral contact plugs 341a and second peripheral wires 341b may be disposed within the third and fourth peripheral lower insulating films 327 and 328. The second peripheral contact plugs 341a and the second peripheral wires 341b may be disposed on the second surface 200_S2 of the peripheral active substrate 200.

The second peripheral contact plugs 341a and the second peripheral wires 341b may be connected to first source/drain regions disposed on at least one side of the second peripheral gate structures PG2. Although not explicitly illustrated, the second peripheral contact plugs 341a and the second peripheral wires 341b may be connected to the conductive patterns (323 and 325) of the second peripheral gate structures PG2. For example, the second peripheral wires 341b may be the closest wires to the second peripheral gate structures PG2 in the third direction DR3.

The second peripheral contact plugs 341a and the second peripheral wires 341b are illustrated as being different films, but the present disclosure is not limited thereto. The second peripheral contact plugs 341a and the second peripheral wires 341b may include a conductive material.

The peripheral connection through plugs 343 may be disposed between the second peripheral wires 341b and the second cell connection wires 282b. The peripheral connection through plugs 343 may connect the second peripheral wires 341b and the second cell connection wires 282b.

The peripheral connection through plugs 343 may penetrate (i.e., extend in) the peripheral active substrate 200 in the third direction DR3. For example, the peripheral connection through plugs 343 may penetrate the peripheral semiconductor isolation films 200SI.

The peripheral connection through plugs 343 may include a conductive material.

A sixth peripheral upper insulating film 276, a seventh peripheral upper insulating film 277, and an eighth peripheral upper insulating film 278 may be disposed on the second peripheral contact plugs 341a and the second peripheral wires 341b. The sixth, seventh, and eighth peripheral upper insulating films 276, 277, and 278 may include an insulating material. Alternatively, contrary to what is illustrated, a single insulating film may be disposed on the second peripheral contact plugs 341a and the second peripheral wires 341b.

Second peripheral connection structures (342a and 342b) may be connected to the second peripheral wires 341b. The second peripheral connection structures (342a and 342b) may include second peripheral connection vias 342a and second peripheral connection wires 342b.

The second peripheral connection vias 342a and the second peripheral connection wires 342b may include a conductive material.

The second peripheral connection vias 342a and the second periphery connection wires 342b are illustrated as being different films, but the present disclosure is not limited thereto. The second periphery connection structures (342a and 342b) are illustrated as including second periphery connection wires 342b disposed at a single metal level, but the present disclosure is not limited thereto. Alternatively, contrary to what is illustrated, the second periphery connection structures (342a and 342b) may include multiple second periphery connection wires 342b disposed at two different metal levels.

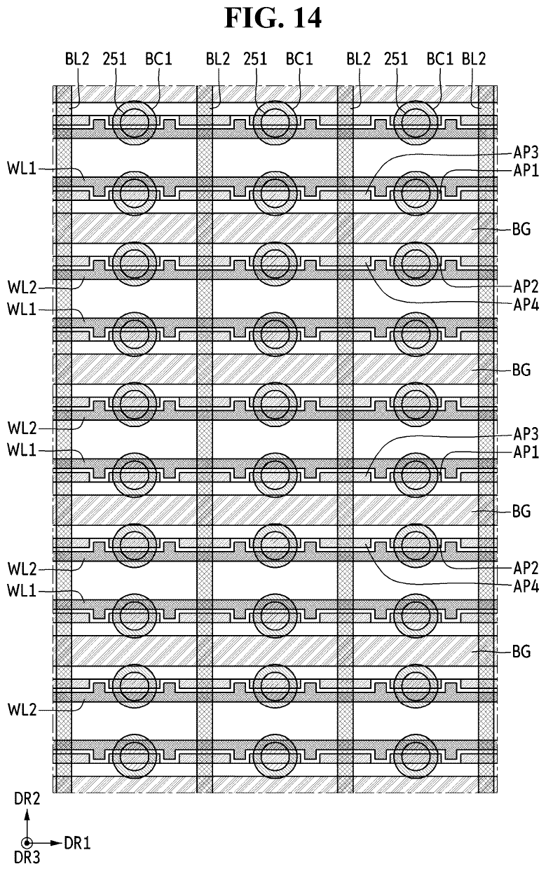

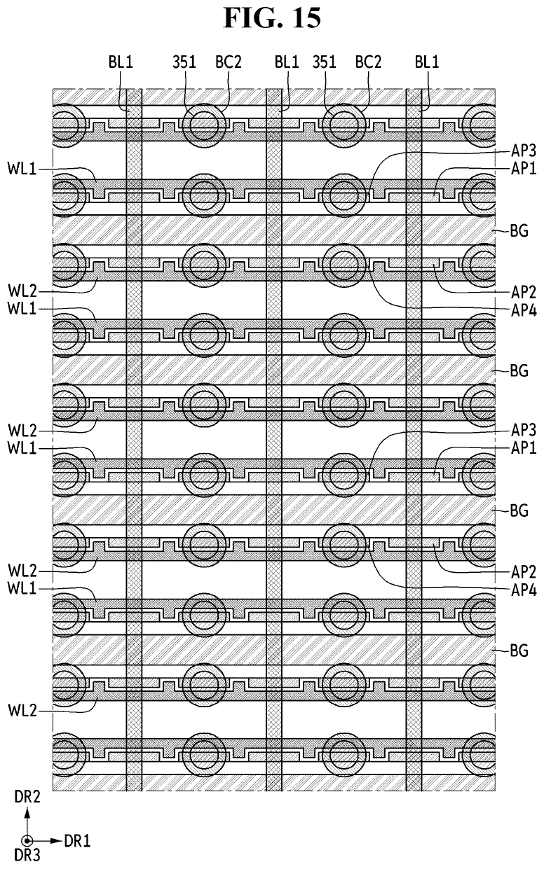

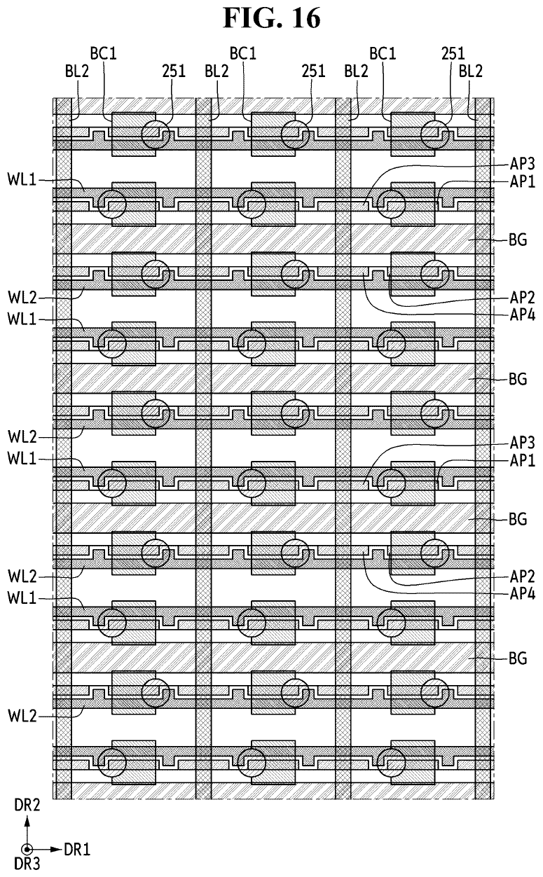

FIGS. 14 and 15 are schematic top plan diagrams for explaining a semiconductor memory device according to some embodiments. FIG. 16 is a schematic top plan diagram for explaining a semiconductor memory device according to some embodiments. For convenience, the embodiments of FIGS. 14 through 16 will hereinafter be described, focusing mainly on the differences from what has been described with reference to FIGS. 1 through 8.

For reference, FIGS. 14 and 16 illustrate example positional relationships between the first data storage patterns, the first contact patterns, and the second bitlines of FIG. 1, and FIG. 15 illustrates the positional relationships between the second data storage patterns, the second contact patterns, and the first bitlines of FIG. 1.

Referring to FIGS. 14 and 15, the first contact patterns BC1 may be circular from a planar perspective.

From a planar perspective, the second contact patterns BC2 may be circular.

Alternatively, contrary to what is illustrated, in one example embodiment, the first contact patterns BC1 and the second contact patterns BC2 may have an elliptical shape from a planar perspective. In another example embodiment, as illustrated in FIGS. 2 and 3, either the first contact patterns BC1 or the second contact patterns BC2 may be rectangular from a planar perspective.

Referring to FIG. 16, the first data storage patterns DSP1, as represented by first storage electrodes 251, may be misaligned with (i.e., offset from) the first contact patterns BC1 from a planar perspective (i.e., in the first direction DR1 and/or the second direction DR2).

Although not explicitly illustrated, the second data storage patterns DSP2 of FIG. 3 may be misaligned with the second contact patterns BC2 from a planar perspective.

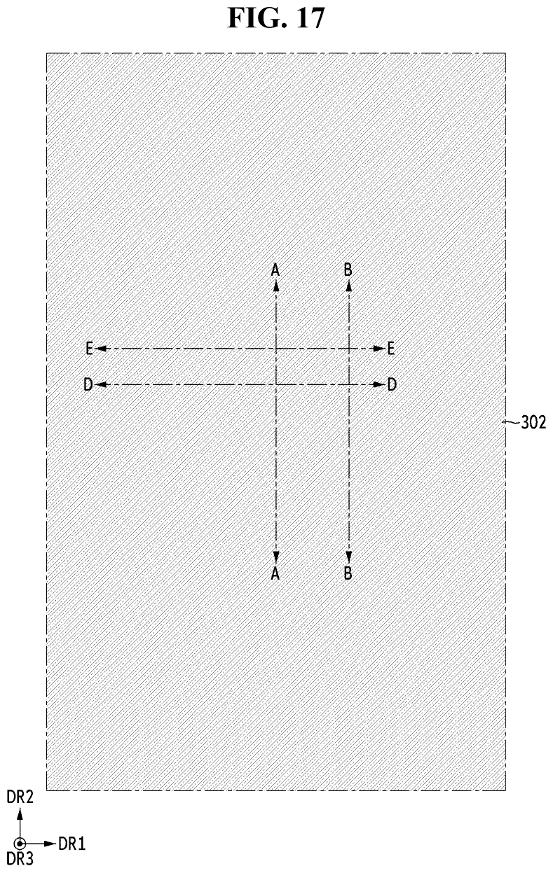

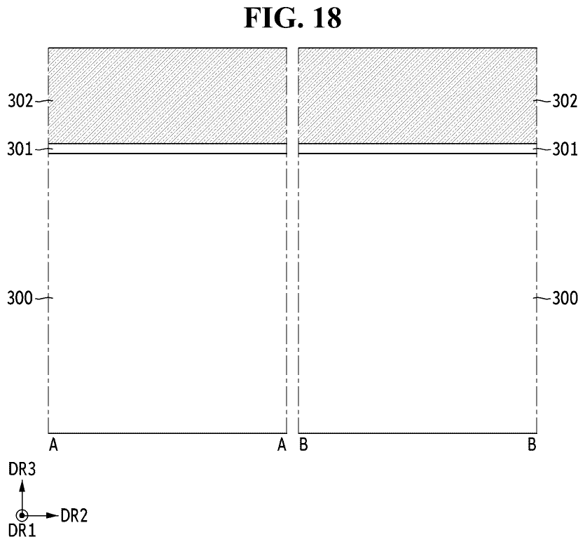

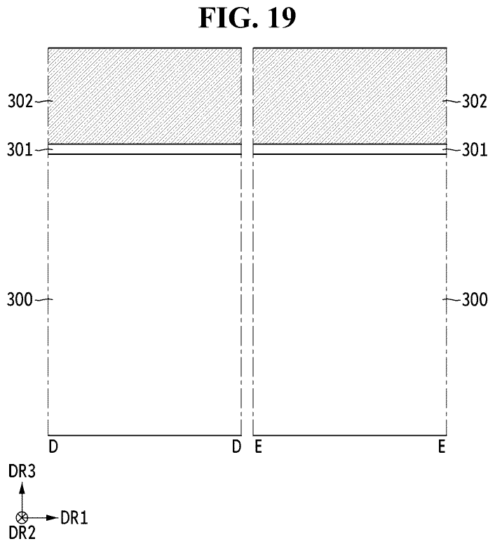

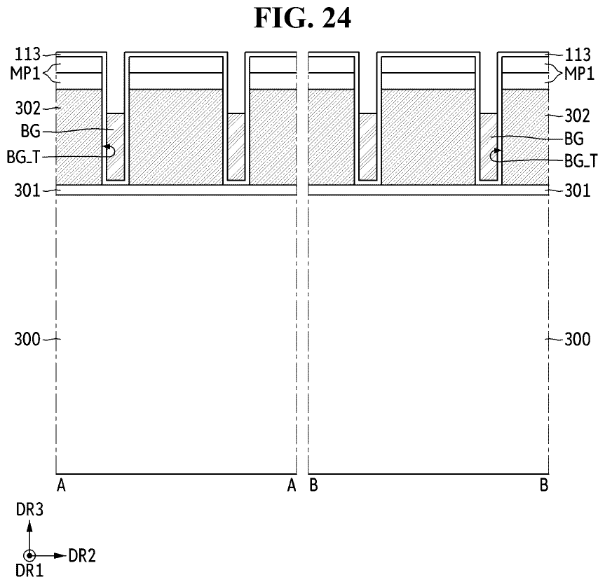

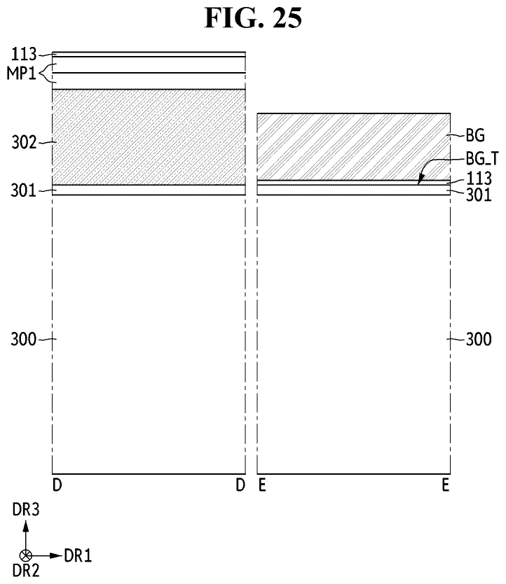

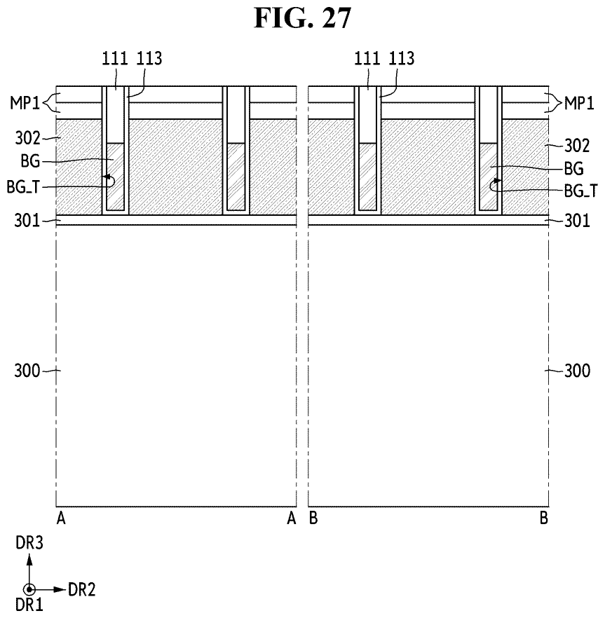

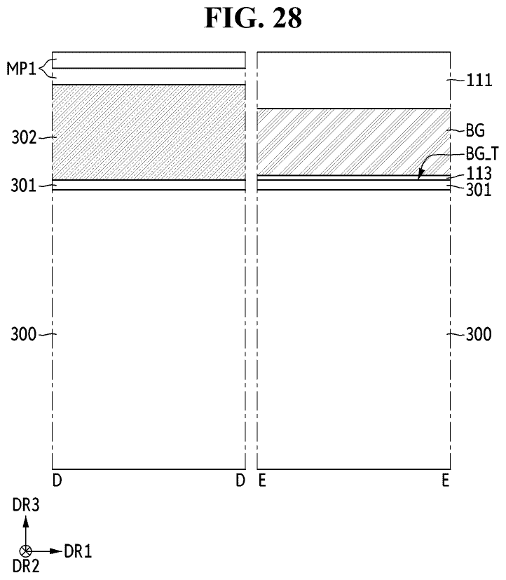

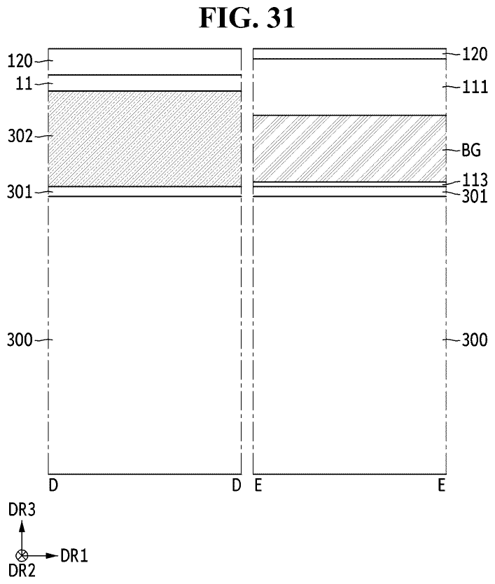

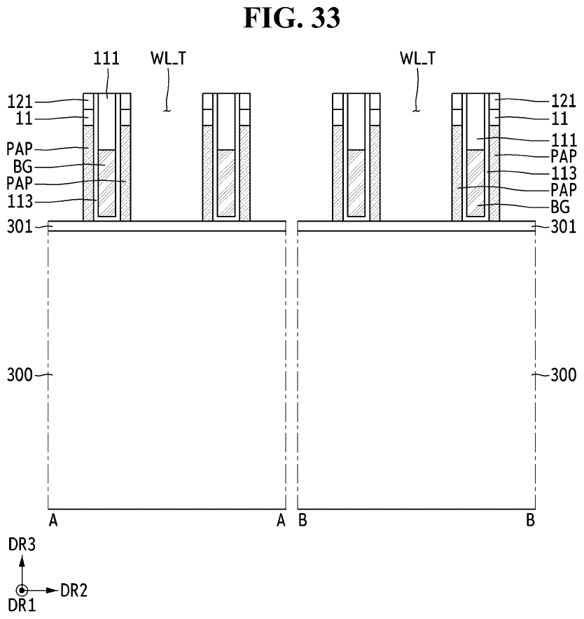

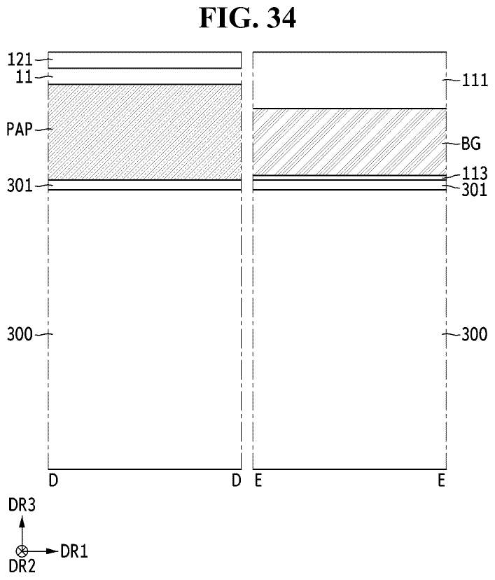

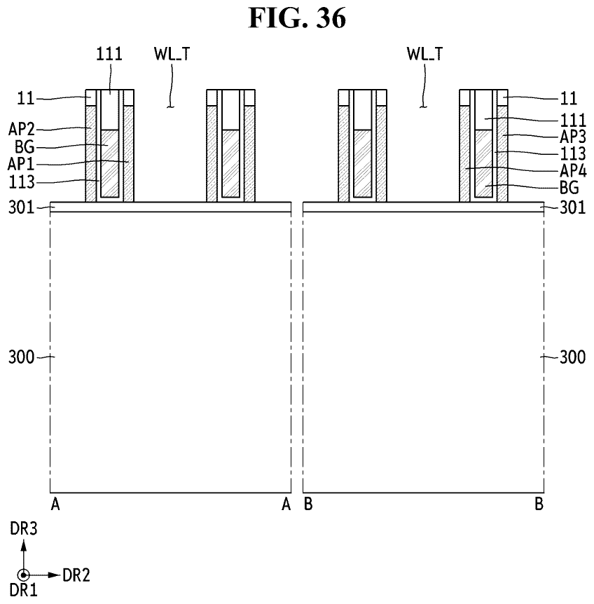

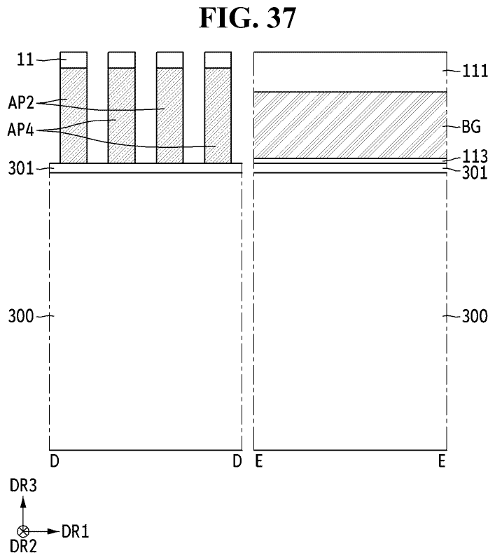

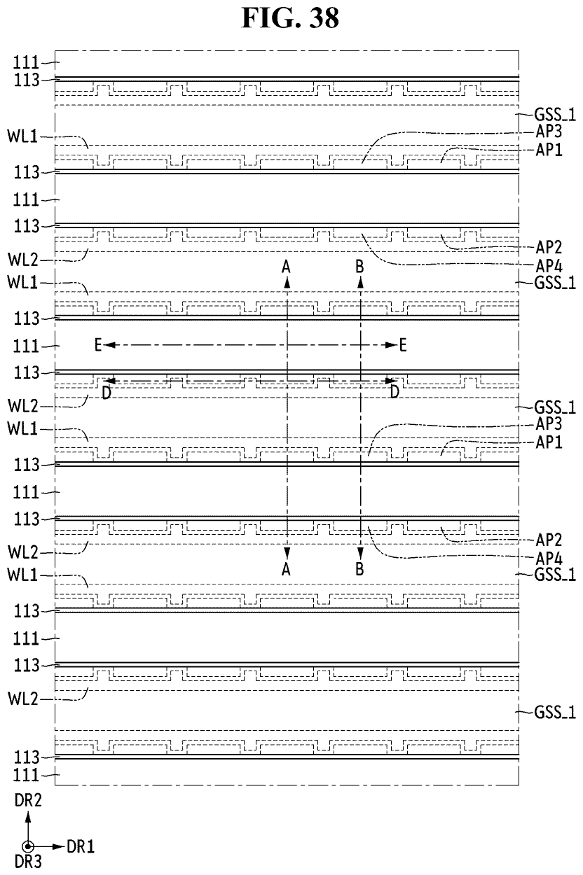

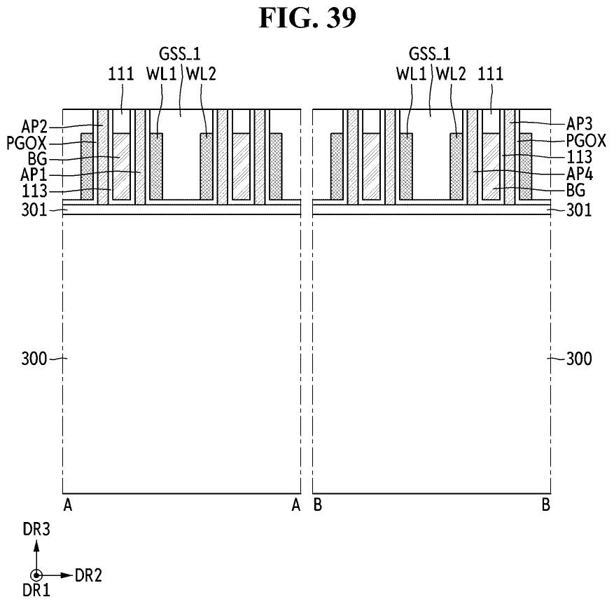

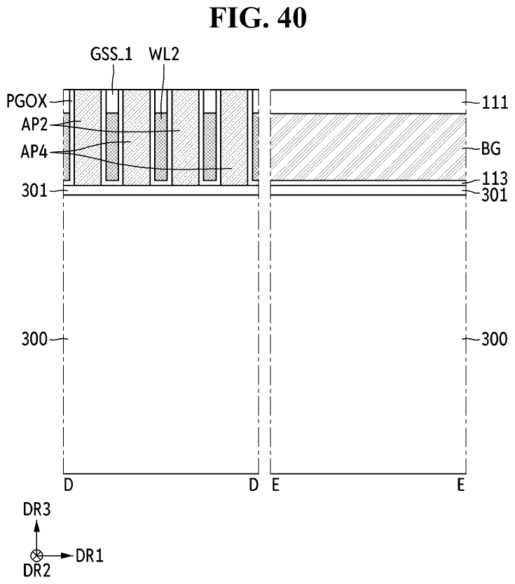

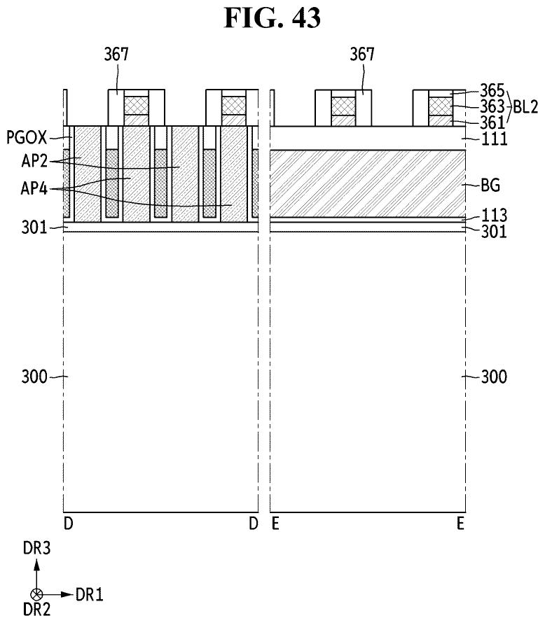

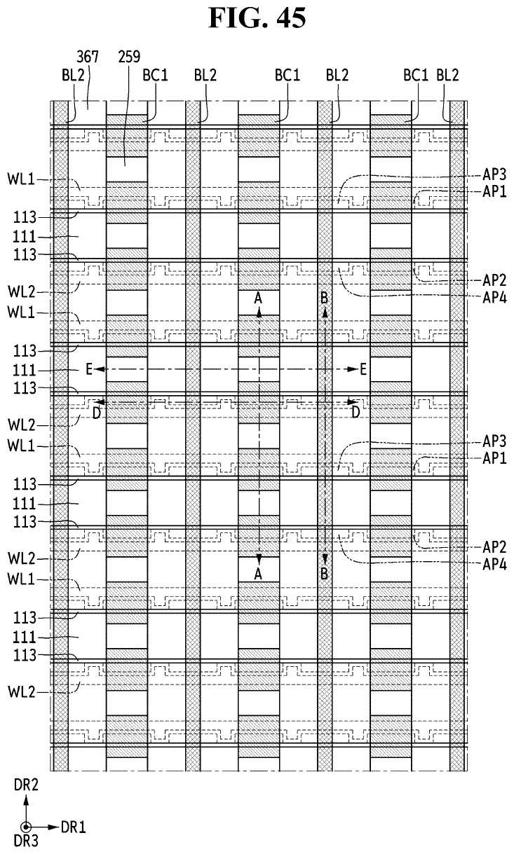

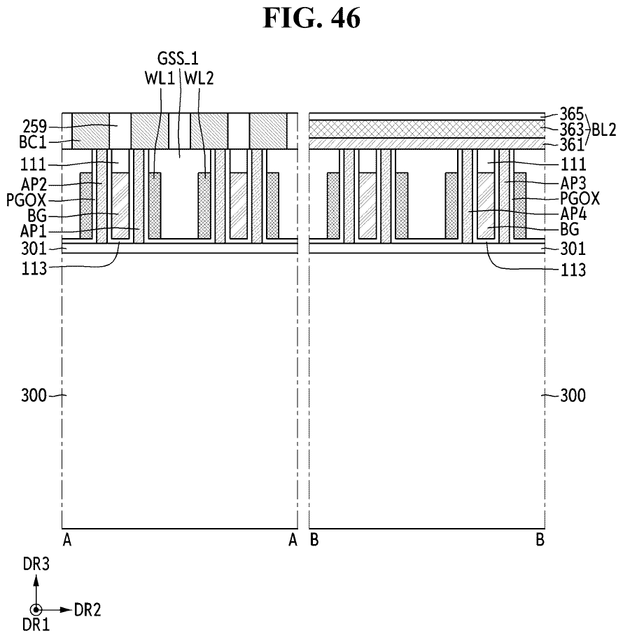

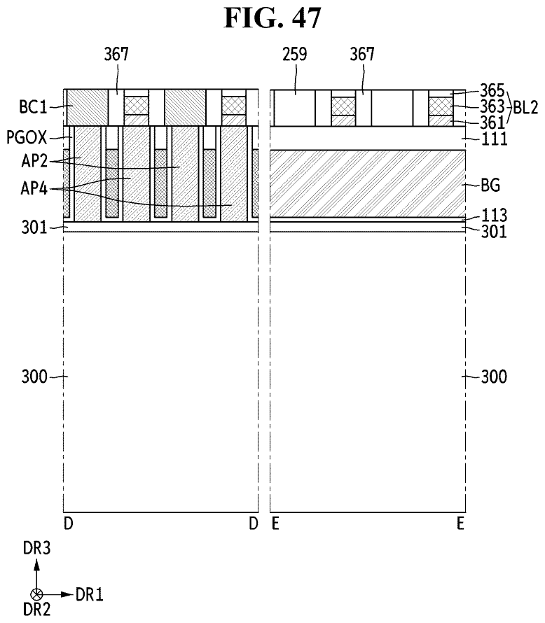

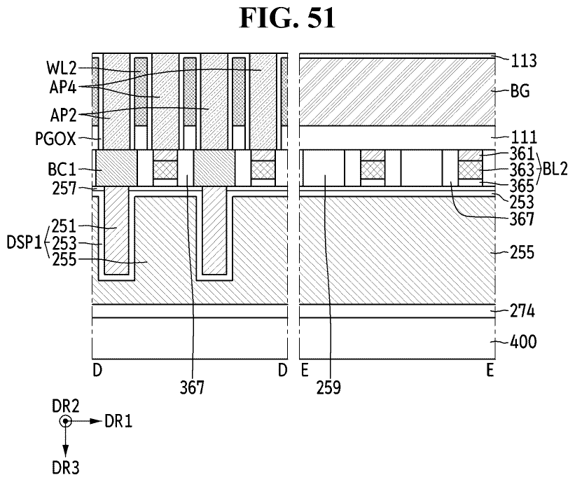

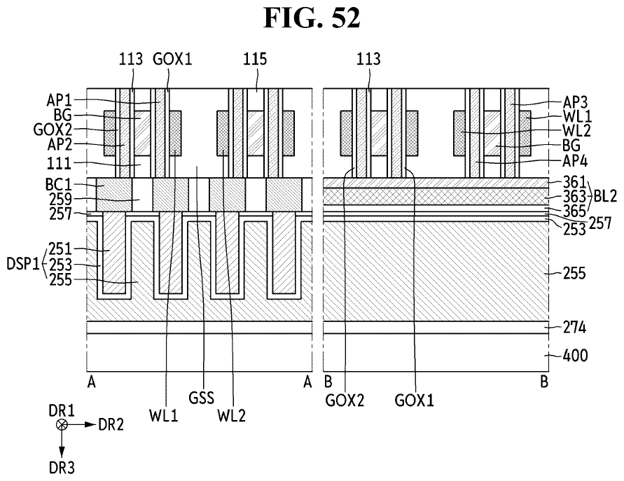

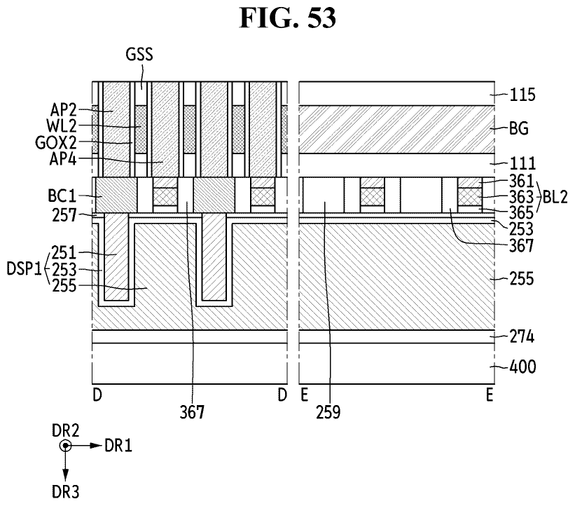

FIGS. 17 through 55 are schematic diagrams for explaining intermediate steps of an example method of manufacturing a semiconductor memory device according to some embodiments. Through this method, the semiconductor memory device described above with reference to FIGS. 1 through 8 can be manufactured.

Referring to FIGS. 17 through 19, a sub-substrate structure including a first sub-substrate 300, a buried insulating layer 301, and an active layer 302 may be provided.

The buried insulating layer 301 and the active layer 302 may be provided on the first sub-substrate 300. The first sub-substrate 300, the buried insulating layer 301, and the active layer 302 may form a silicon-on-insulator (SOI) substrate. The first sub-substrate 300 may be a semiconductor substrate. For example, the first sub-substrate 300 may be a silicon substrate, a germanium substrate, and/or a silicon-germanium substrate. The first sub-substrate 300 will hereinafter be described as being a silicon substrate.

The buried insulating layer 301 may be a buried oxide (BOX) formed by a Separation by Implanted Oxygen (SIMOX) method or a bonding-and-layer transfer method. Alternatively, the buried insulating layer 301 may be an insulating film formed by chemical vapor deposition (CVD). The buried insulating layer 301 may include, for example, a silicon oxide film, a silicon nitride film, a silicon oxynitride film, and/or a low dielectric constant (low-k) insulating film.

The active layer 302 may be a monocrystalline semiconductor film. The active layer 302 may be, for example, a monocrystalline silicon substrate, a germanium substrate, and/or a silicon-germanium substrate. The active layer 302 may have first and second surfaces opposite to each other in a third direction DR3, and the second surface of the active layer 302 may be in contact with the buried insulating layer 301.

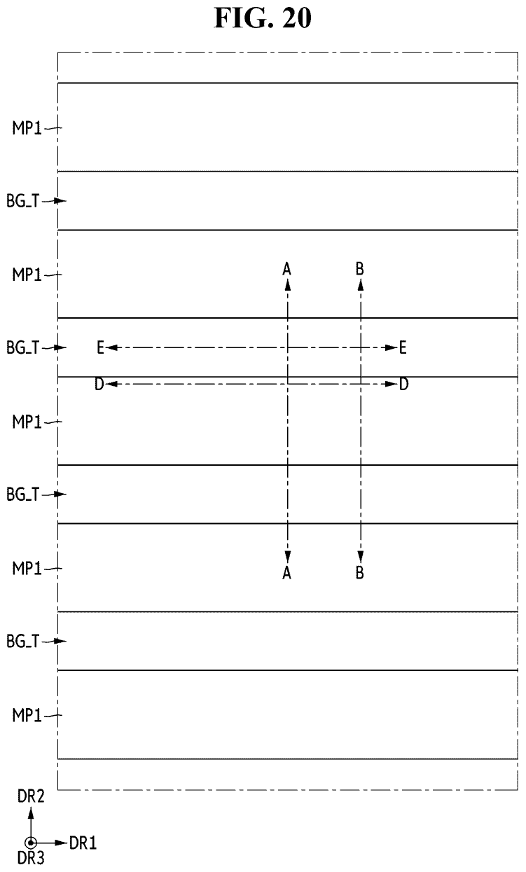

Referring to FIGS. 20 through 22, a mask pattern MP1 may be formed on the active layer 302.

The mask pattern MP1 may have line-shaped openings extending in the first direction DR1. The mask pattern MP1 may include a first lower mask film 11 and a first upper mask film 12 that are sequentially stacked in the third direction DR3. The first upper mask film 12 may be formed of a material having etching selectivity with respect to the first lower mask film 11. For example, the first lower mask film 11 may include, but is not limited to, silicon oxide, and the first upper mask film 12 may include, but is not limited to, silicon nitride.

Thereafter, using the mask pattern MP1 as an etching mask, the active layer 302 may be anisotropically etched. As a result, back gate trenches BG_T extending in the first direction DR1 may be formed in the active layer 302. The back gate trenches BG_T may expose the buried insulating layer 301 (through a bottom of the back gate trenches BG_T) and may be spaced apart at regular intervals in a second direction DR2. The term “expose” (or “exposed,” or like terms) may be used herein to describe relationships between elements and/or with reference to intermediate processes in fabricating a semiconductor device, but may not require exposure of a particular element in the completed device. Likewise, the term “not exposed” may be used to described relationships between elements and/or with reference to intermediate processes in fabricating a semiconductor device, but may not require a particular element to be unexposed in the completed device.

Alternatively, contrary to what is illustrated, during the formation of the back gate trenches BG_T, at least part of the buried insulating layer 301 may be removed.

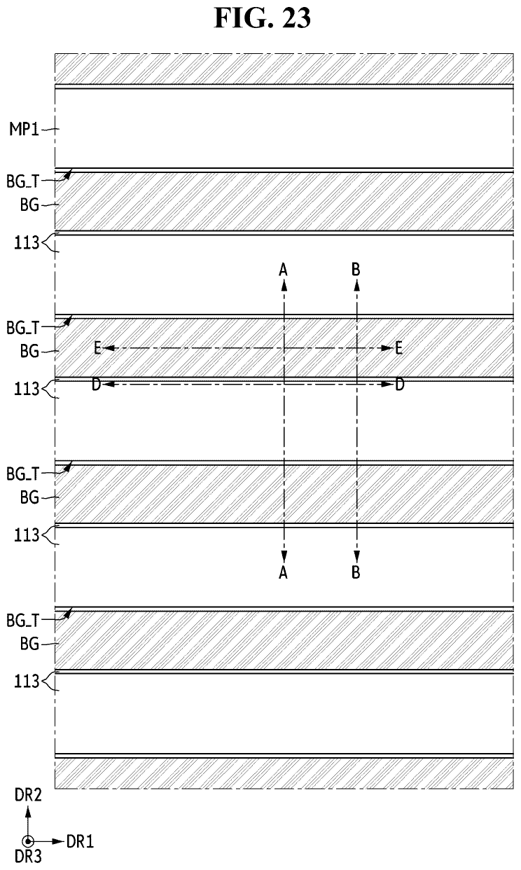

Referring to FIGS. 23 through 25, back gate insulating patterns 113 and back gate electrodes BG may be formed within the back gate trenches BG_T.

Specifically, the back gate insulating patterns 113 may be conformally formed along the sidewalls and lower surfaces of the back gate trenches BG_T, and along the upper surface of the mask pattern MP1. The term “conformally” (or “conformal,” or like terms), as may be used herein in the context of a material layer or coating, is intended to refer broadly to a material layer or coating having a substantially uniform cross-sectional thickness relative to the contour of a surface to which the material layer is applied. A back gate conductive film may be formed on the back gate insulating patterns 113. The back gate conductive film may fill the back gate trenches BG_T. Thereafter, by isotropically etching the back gate conductive film, back gate electrodes BG extending in the first direction DR1 may be formed. The back gate electrodes BG may fill portions of the back gate trenches BG_T.

Meanwhile, in some embodiments, before the formation of the back gate insulating patterns 113, a gas-phase doping (GPD) process or a plasma doping (PLAD) process may be performed. Through this, impurities may be doped into portions of the active layer 302 exposed by the back gate trenches BG_T.

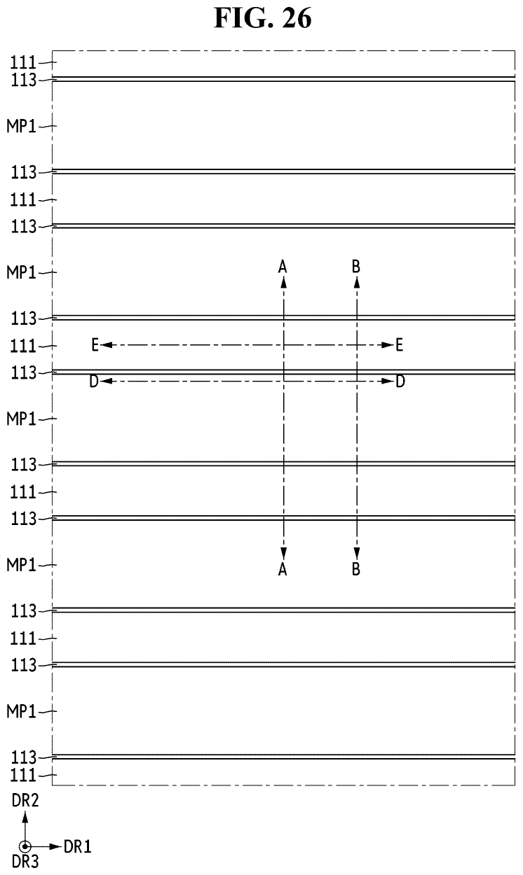

Referring to FIGS. 26 through 28, back gate isolation patterns 111 may be formed on the back gate electrodes BG.

The back gate isolation patterns 111 may fill other portions of the back gate trenches BG_T. If the back gate isolation patterns 111 and the back gate insulating patterns 113 are formed of the same material (e.g., silicon oxide), then during the formation of the back gate isolation patterns 111, the back gate insulating patterns 113 may be removed from above the upper surface of the mask pattern MP1.

Meanwhile, before the formation of the back gate isolation patterns 111, a GPD process or a PLAD process may be performed. Through this, impurities may be doped into the active layer 302 through the back gate trenches BG_T where the back gate electrodes BG are formed.

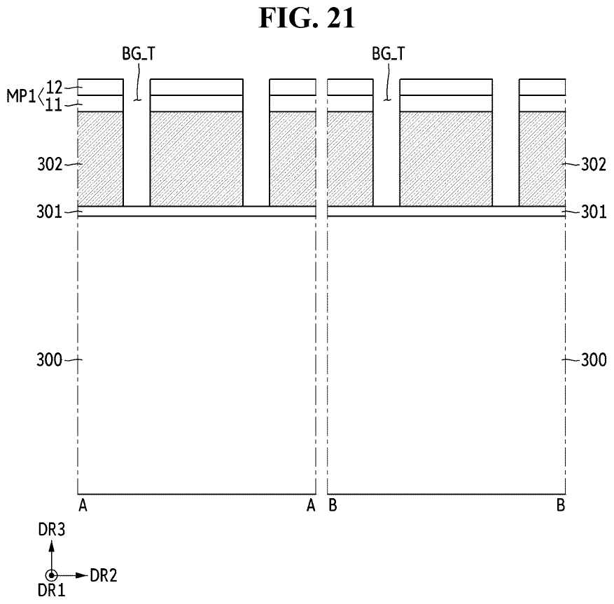

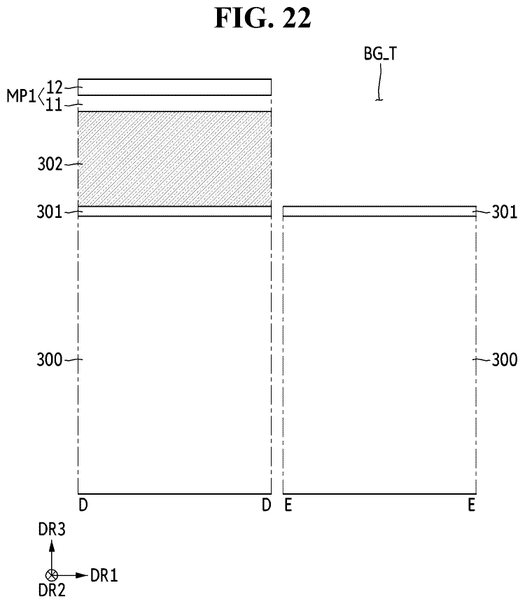

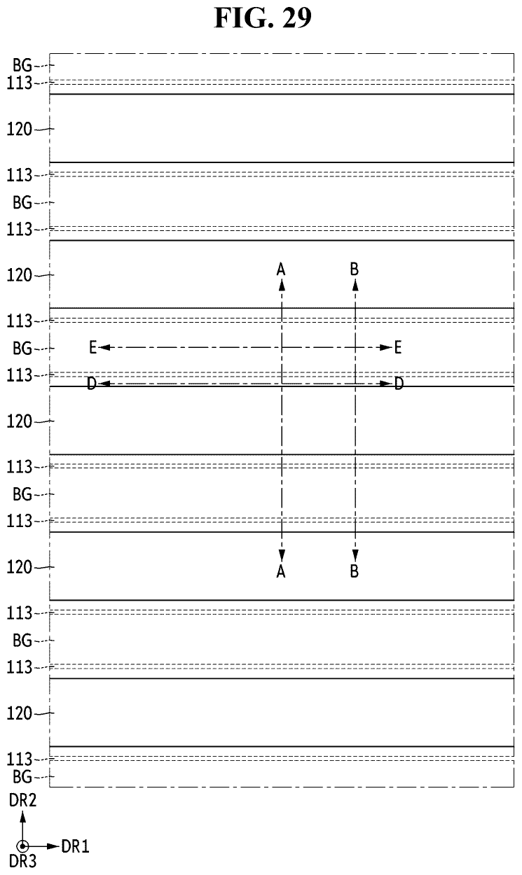

Referring to FIGS. 29 through 31, after the formation of the back gate isolation patterns 111, the first upper mask film 12 (see FIGS. 21 and 22) may be removed.

The back gate isolation patterns 111 may have a shape extending above the upper surface of the first lower mask film 11 in the third direction DR3.

Thereafter, a spacer film 120 may be formed along the upper surface of the first lower mask film 11, the sidewalls of the back gate insulating patterns 113, and the upper surfaces of the back gate isolation patterns 111. The spacer film 120 may be formed with a uniform thickness. Depending on the deposition thickness of the spacer film 120, the width of the active patterns of vertical channel transistors may be determined.

The spacer film 120 may be formed of an insulating material. For example, the spacer film 120 may include silicon oxide, silicon oxynitride, silicon nitride, silicon carbide, silicon carbonitride, or a combination thereof.

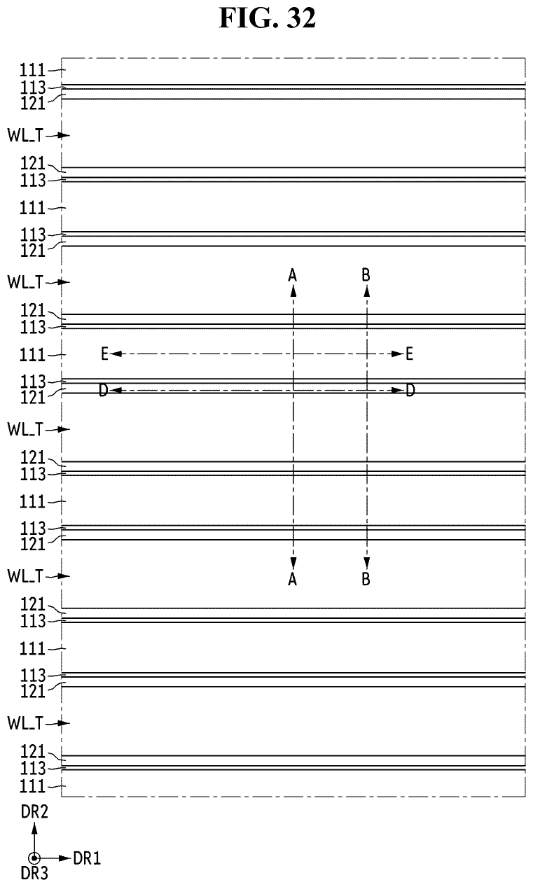

Referring to FIGS. 32 through 34, an anisotropic etching process may be performed on the spacer film 120, thereby forming a pair of spacer patterns 121 on the sidewalls of each of the back gate insulating patterns 113.

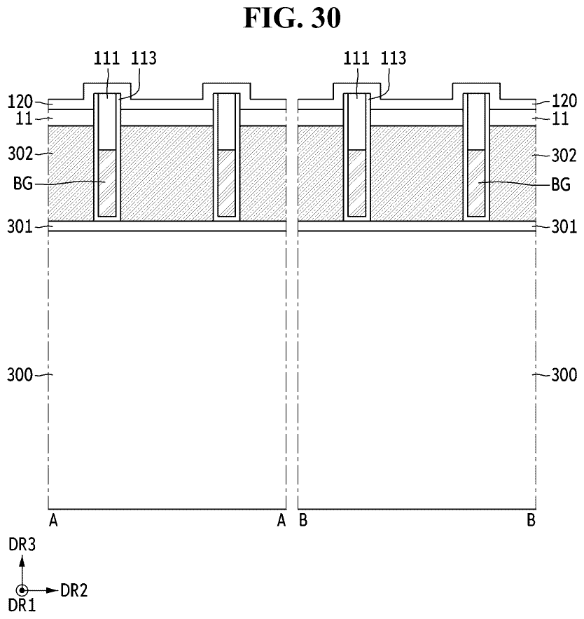

Using the spacer patterns 121 as an etching mask, an anisotropic etching process may be performed on the active layer 302 (see FIG. 30). Through this, a pair of pre-active patterns PAP, separated from each other, may be formed on both sides of each of the back gate insulating patterns 113. As the pre-active patterns PAP are formed, the buried insulating layer 301 may be exposed.

The pre-active patterns PAP may extend in the first direction DR1 parallel to the back gate electrodes BG. During the formation of the pre-active patterns PAP, wordline trenches WL_T may be formed between adjacent pre-active patterns PAP in the second direction DR2.

Referring to FIGS. 32 through 37, a sacrificial film that fills the wordline trenches WL_T may be formed. A pattern mask may be formed on the sacrificial film. The pattern mask may have a line shape extending in the second direction DR2. Alternatively, the pattern mask may have a line shape extending diagonally with respect to both the first and second directions DR1 and DR2. Using the pattern mask as an etch mask, the sacrificial film may be etched to form sacrificial openings in the sacrificial film.

By etching the pre-active patterns PAP exposed through the sacrificial openings, first active patterns AP1, second active patterns AP2, third active patterns AP3, and fourth active patterns AP4 may be formed on both sides of the back gate electrodes BG. On the first sidewalls of the back gate electrodes BG, the first active patterns AP1 and the third active patterns AP3 may be alternately formed along the first direction DR1. On the second sidewalls of the back gate electrodes BG, the second active patterns AP2 and the fourth active patterns AP4 may be alternately formed along the first direction DR1. As the first active patterns AP1 through the fourth active patterns AP4 are formed, the sacrificial openings may expose portions of the back gate insulating patterns 113.

Thereafter, the sacrificial film, the pattern mask, and the spacer patterns 121 may be removed. The first lower mask film 11 may remain on the first active patterns AP1 through the fourth active patterns AP4. The buried insulating layer 301 may be exposed.

Alternatively, contrary to what is illustrated, the first lower mask film 11 may be removed, exposing the upper surfaces of the first active patterns AP1 through the fourth active patterns AP4.

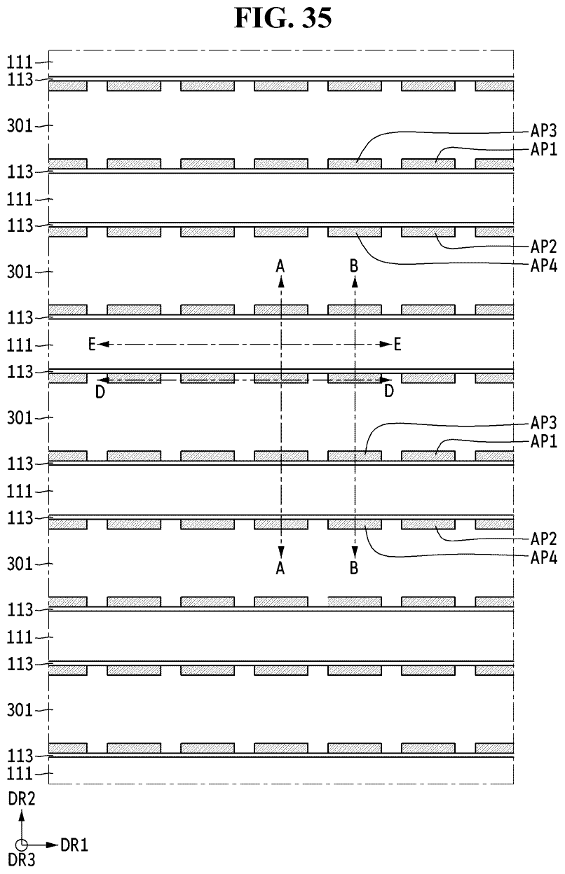

Referring to FIGS. 35 through 40, pre-gate insulating patterns PGOX may be formed along the sidewalls and lower surfaces of the wordline trenches WL_T.

The pre-gate insulating patterns PGOX may be formed along the sidewalls of the first active patterns AP1 through the fourth active patterns AP4, and along the upper surface of the buried insulating layer 301.

The pre-gate insulating patterns PGOX may be formed using at least one of physical vapor deposition (PVD), thermal CVD, low-pressure CVD (LP-CVD), plasma-enhanced CVD (PE-CVD), or atomic layer deposition (ALD) techniques, but the present disclosure is not limited thereto.

Thereafter, the first wordlines WL1 and the second wordlines WL2 may be formed on the pre-gate insulating patterns PGOX. The first wordlines WL1 may be formed on the sidewalls of the first active patterns AP1 and the sidewalls of the third active patterns AP3. The second wordlines WL2 may be formed on the sidewalls of the second active patterns AP2 and the sidewalls of the fourth active patterns AP4. Alternatively, contrary to what is illustrated, while the first wordlines WL1 and the second wordlines WL2 are being formed, the pre-gate insulating patterns PGOX may be etched, exposing the buried insulating layer 301.

Thereafter, pre-gate separation patterns GSS_1 may be formed on the first wordlines WL1 and the second wordlines WL2. The pre-gate separation patterns GSS_1 may fill the wordline trenches WL_T. The upper surfaces of the pre-gate separation patterns GSS_1 may be positioned on the same plane as the upper surfaces of the back gate isolation patterns 111; that is, the upper surfaces of the pre-gate separation patterns GSS_1 may be coplanar with the upper surfaces of the back gate isolation patterns 111, relative to a surface of the first sub-substrate 300 as a reference layer. During the formation of the pre-gate separation patterns GSS_1, the first lower mask film 11 may be removed, exposing the first active patterns AP1 through the fourth active patterns AP4.

Alternatively, contrary to the above description, the first lower mask film 11 may be removed during the formation of the first wordlines WL1 and the second wordlines WL2, exposing the first through fourth active patterns AP1, AP2, AP3, and AP4.

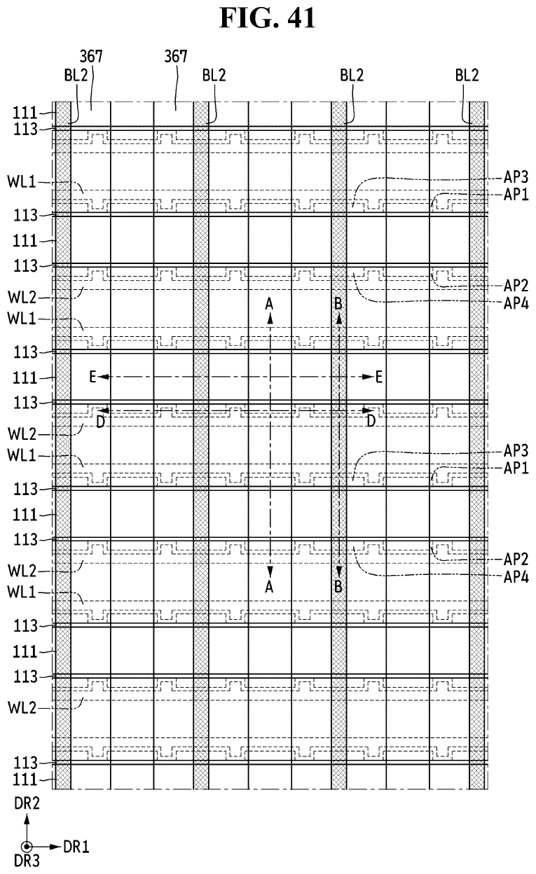

Referring to FIGS. 41 through 43, second bitlines BL2 may be formed on the pre-gate separation patterns GSS_1.

The second bitlines BL2 may be formed on the third active patterns AP3 and the fourth active patterns AP4. The second bitlines BL2 may also be formed on the first active patterns AP1 and the second active patterns AP2.

Thereafter, second bitline spacers 367 may be formed along the sidewalls of the second bitlines BL2.

The first active patterns AP1 and the second active patterns AP2 may be exposed between adjacent second bitlines BL2 in the first direction DR1.

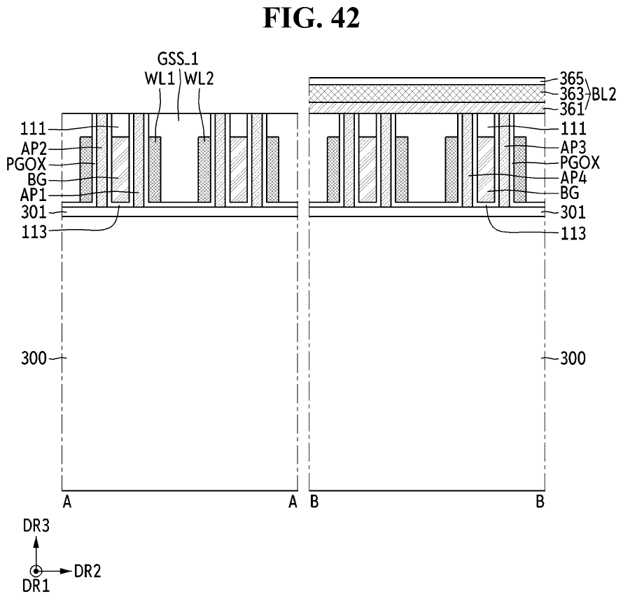

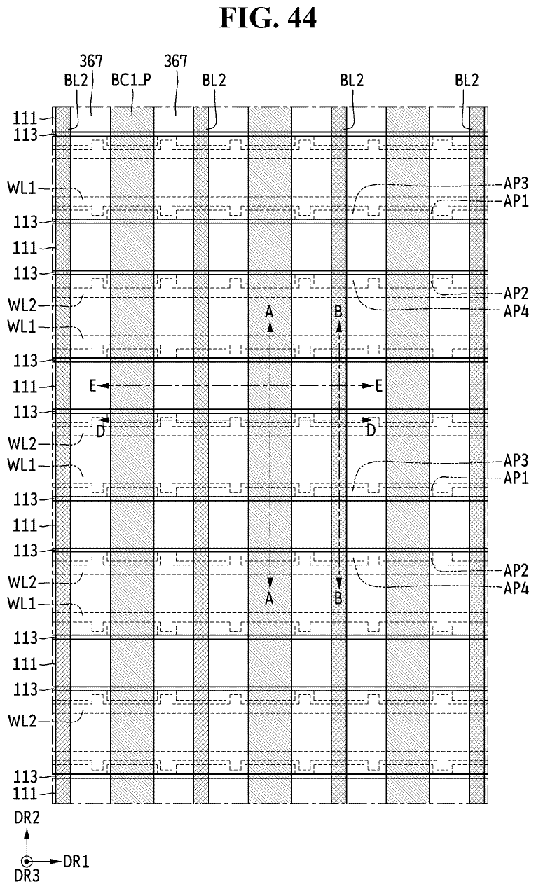

Referring to FIG. 44, a first contact film BC1_P may be formed on the pre-gate separation patterns GSS_1 (see FIG. 42).

The first contact film BC1_P may be formed between adjacent second bitlines BL2 in the first direction DR1. The first contact film BC1_P may be formed on the first active patterns AP1 and the second active patterns AP2.

Referring to FIGS. 44 through 47, the first contact film BC1_P may be patterned, thereby forming first contact patterns BC1.

The first contact patterns BC1 may be formed on the first active patterns AP1 and the second active patterns AP2. The first contact patterns BC1 may be connected to the first active patterns AP1 and the second active patterns AP2.

A first fence pattern 259 may be formed between adjacent second bitline spacers 367 in the first direction DR1. The first contact film BC1_P may be patterned using the first fence pattern 259.

Contrary to what is illustrated in FIGS. 44 through 47, a mold film may be formed between the adjacent second bitlines BL2 in the first direction DR1. Contact holes may be formed in the mold film. The contact holes may expose the first active patterns AP1 and the second active patterns AP2. Thereafter, the first contact patterns BC1 may be formed in the contact holes. The first contact patterns BC1 may fill the contact holes.

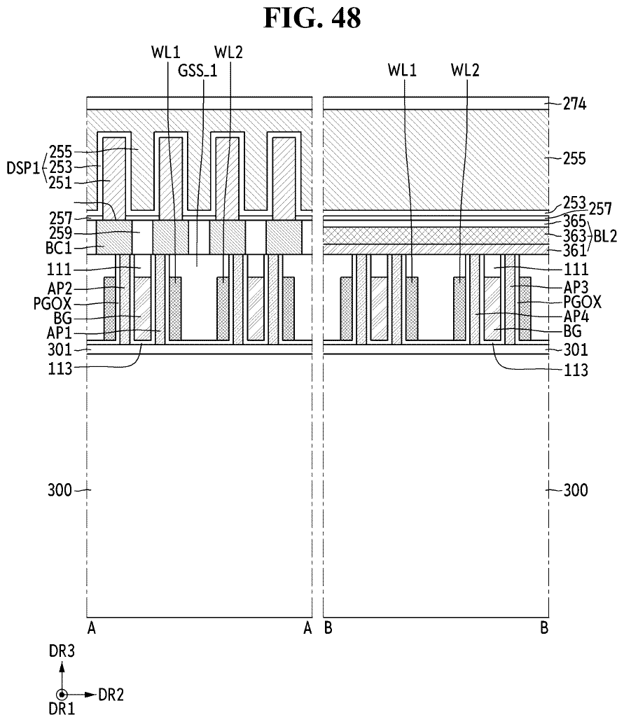

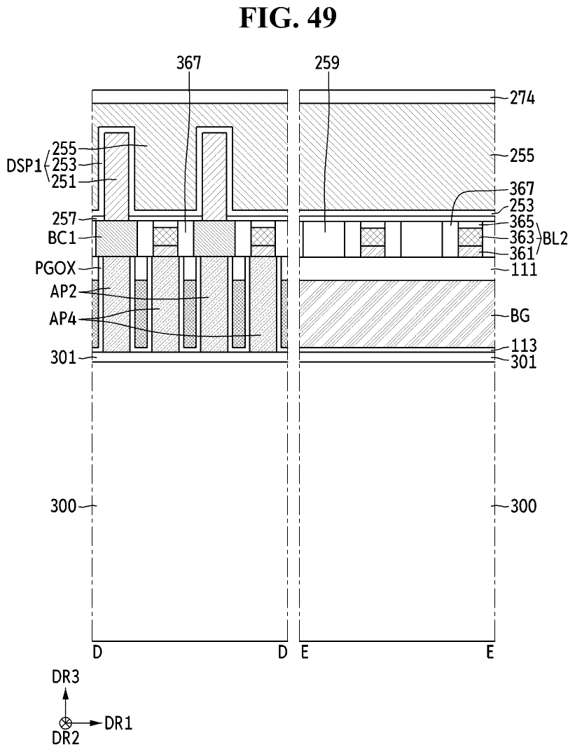

Referring to FIGS. 48 and 49, first data storage patterns DSP1 may be formed on the first contact patterns BC1.

The first data storage patterns DSP1 may be electrically connected to the respective first contact patterns BC1.

A first cell upper insulating film 274 may be formed on the first data storage patterns DSP1.

Referring to FIGS. 48 through 51, the first sub-substrate 300 where the back gate electrodes BG, the wordlines (WL1 and WL2), the active patterns (AP1 through AP4), the second bitlines BL2, and the first data storage patterns DSP1 are formed may be bonded to a second sub-substrate 400. In one or more embodiments, the second sub-substrate 400 may contact the first cell upper insulating film 274.

The back gate electrodes BG, the wordlines (WL1 and WL2), the active patterns (AP1 through AP4), the second bitlines BL2, and the first data storage patterns DSP1 may be disposed between the first and second sub-substrates 300 and 400.

In one example, the second sub-substrate 400 may be a semiconductor substrate. In another example, the second sub-substrate 400 may be an insulating substrate including an insulating material.

Thereafter, after bonding the first and second sub-substrates 300 and 400, a back-side lapping process may be performed to remove the first sub-substrate 300.

Removing the first sub-substrate 300 may involve sequentially performing a grinding process and a wet etching process to expose the buried insulating layer 301.

Thereafter, the buried insulating layer 301 may be removed, exposing the first active patterns AP1 through the fourth active patterns AP4. As the buried insulating layer 301 is removed, portions of the back gate insulating patterns 113 and portions of the pre-gate insulating patterns PGOX may be exposed.

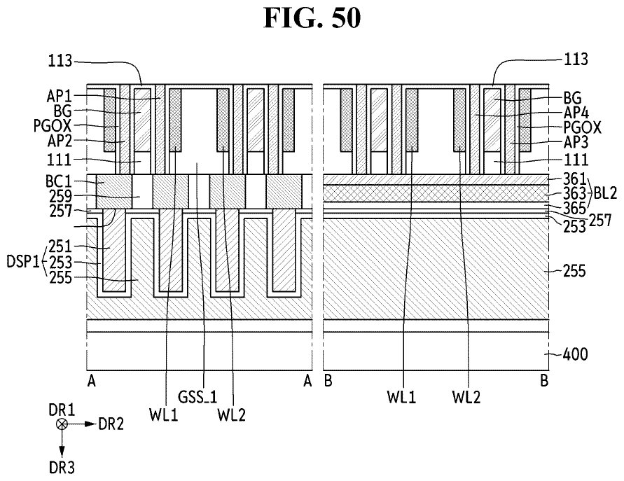

Referring to FIGS. 50 through 53, the exposed portions of the back gate insulating patterns 113 may be removed.

As a result, the back gate electrodes BG may be exposed. By performing an etch-back process, portions of the exposed back gate electrodes BG may be removed. A back gate capping pattern 115 may be formed on the recessed back gate electrodes BG.

Additionally, the exposed portions of the pre-gate insulating patterns PGOX may be removed, thereby forming first gate insulating patterns GOX1 and second gate insulating patterns GOX2. Portions of the pre-gate insulating patterns PGOX may be removed, exposing the first wordlines WL1 and the second wordlines WL2. An etch-back process may be performed to remove portions of the exposed first wordlines WL1 and portions of the exposed second wordlines WL2. An insulating material may fill the recessed first wordlines WL1 and the recessed second wordlines WL2. As a result, gate separation patterns GSS may be formed.

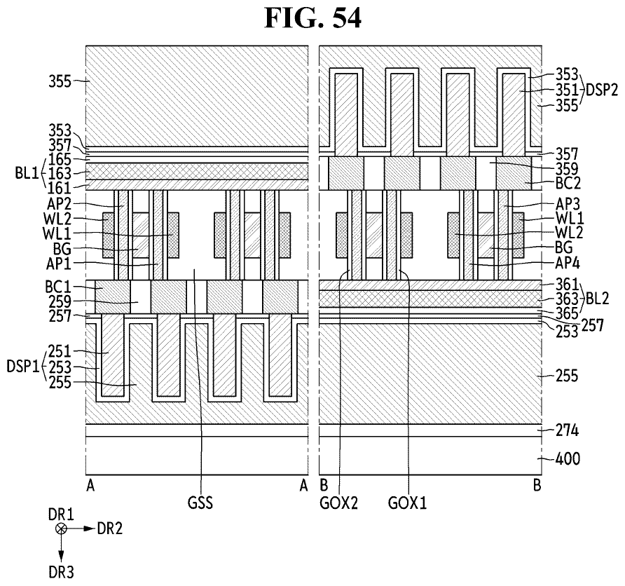

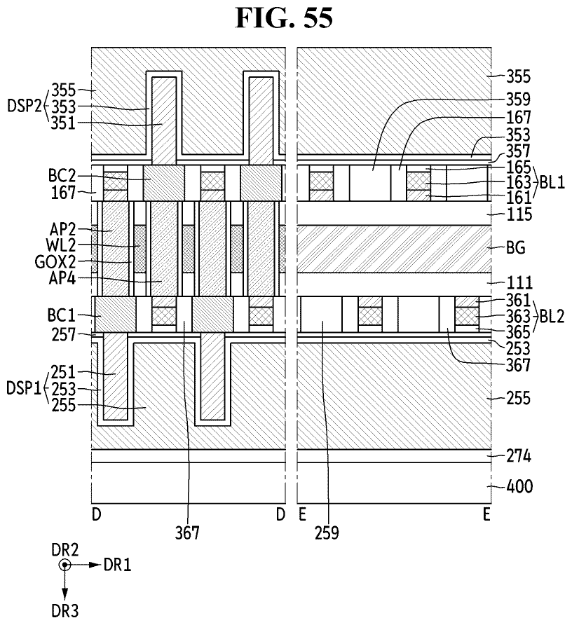

Referring to FIGS. 54 and 55, first bitlines BL1 may be formed on the first active patterns AP1 and the second active patterns AP2.

First bitline spacers 167 may be formed along the sidewalls of the first bitlines BL1.

Thereafter, second contact patterns BC2 may be formed on the third active patterns AP3 and the fourth active patterns AP4. Second data storage patterns DSP2 may be formed on the second contact patterns BC2.

Thereafter, referring to FIGS. 4 and 6, upper pad plugs BPPG2 and upper bonding pads BP2 may be formed on the second data storage patterns DSP2.

Thereafter, a substrate 100 where first peripheral gate structures PG1, first peripheral connection structures (242a and 242b), lower bonding pads BP1, and lower pad plugs BPPG1 are formed may be bonded to the second sub-substrate 400.

The second sub-substrate 400 and the substrate 100 may be bonded using a bonding adhesive layer 267. Alternatively, contrary to what is illustrated, the second sub-substrate 400 and the substrate 100 may be bonded without the bonding adhesive layer 267.

Thereafter, the second sub-substrate 400 may be removed.

Alternatively, the first sub-substrate 300 where the back gate electrodes BG, the wordlines (WL1 and WL2), the active patterns (AP1 through AP4), the second bitlines BL2, and the first data storage patterns DSP1 are formed may be bonded to the substrate 100 of FIGS. 11 and 13. After removing the first sub-substrate 300, the first bitlines BL1 and the second data storage patterns DSP2 may be formed. After forming the first bitlines BL1 and the second data storage patterns DSP2, a peripheral active substrate 200 and second peripheral gate structures PG2 may be formed on the second data storage patterns DSP2. Here, the first bitlines BL1 correspond to the second bitlines BL2 of FIGS. 11 and 13, and the second data storage patterns DSP2 correspond to the first data storage patterns DSP1 of FIGS. 11 and 13. In this case, the bitlines and data storage patterns formed on the first sub-substrate 100 in FIGS. 17 through 49 may correspond to the first bitlines BL1 and the second data storage patterns DSP2 of FIGS. 11 and 13.

In concluding the detailed description, those skilled in the art will appreciate that many variations and modifications may be made to the preferred embodiments without substantially departing from the principles of the present inventive concept. Therefore, the disclosed preferred embodiments of the disclosure are used in a generic and descriptive sense only and not for purposes of limitation.

What is claimed is:

1. A semiconductor memory device, comprising:
a first data storage pattern on a substrate;
a second data storage pattern spaced apart from the first data storage pattern in a first direction perpendicular to an upper surface of the substrate;
a first bitline between the first and second data storage patterns, and extending in a second direction parallel to the upper surface of the substrate and perpendicular to the first direction;
a second bitline between the first and second data storage patterns, extending in the second direction, and spaced apart from the first bitline in the first direction;
a wordline between the first and second bitlines, and extending in a third direction parallel to the upper surface of the substrate and perpendicular to the first and second directions;
a first active pattern between the first and second bitlines, and electrically connected to the first data storage pattern; and
a second active pattern between the first and second bitlines, and electrically connected to the second data storage pattern.

2. The semiconductor memory device of claim 1, wherein the first and second active patterns are aligned with each other in the third direction.

3. The semiconductor memory device of claim 2, wherein
each of the first and second active patterns includes first sidewalls and second sidewalls opposite to each other in the second direction,
the wordline is on the first sidewalls of the first and second active patterns, and
the wordline is not on the second sidewalls of the first and second active patterns.

4. The semiconductor memory device of claim 2, further comprising:
a back gate electrode between the first and second bitlines, and extending in the third direction,
wherein the first and second active patterns are between the wordline and the back gate electrode.

5. The semiconductor memory device of claim 1, wherein
the first active pattern is not electrically connected to the second data storage pattern, and
the second active pattern is not electrically connected to the first data storage pattern.

6. The semiconductor memory device of claim 1, wherein
the first bitline is electrically connected to the first active pattern and not electrically connected to the second active pattern, and
the second bitline is electrically connected to the second active pattern and not electrically connected to the first active pattern.

7. The semiconductor memory device of claim 1, further comprising:
a contact pattern between the first data storage pattern and the first active pattern,
wherein the contact pattern overlaps the second bitline in the third direction, and overlaps the first bitline in the first direction.

8. The semiconductor memory device of claim 7, wherein the contact pattern is rectangular when viewed in a plan view.

9. The semiconductor memory device of claim 7, wherein the contact pattern is circular when viewed in a plan view.

10. A semiconductor memory device, comprising:
first and second active patterns on a substrate, each of the first and second active patterns including first surfaces and second surfaces opposite to each other in a first direction perpendicular to an upper surface of the substrate, the respective first surfaces of the first and second active patterns facing the substrate;
a first bitline extending in a second direction parallel to the upper surface of the substrate and perpendicular to the first direction, the first bitline electrically connected to the first surface of the first active pattern;
a second bitline extending in the second direction and electrically connected to the second surface of the second active pattern;
a first wordline between the first and second bitlines and extending in a third direction parallel to the upper surface of the substrate and perpendicular to both the first and second directions;
a first data storage pattern electrically connected to the second surface of the first active pattern; and
a second data storage pattern electrically connected to the first surface of the second active pattern.

11. The semiconductor memory device of claim 10, wherein the first and second active patterns are aligned with each other in the third direction.

12. The semiconductor memory device of claim 10, further comprising:
a third active pattern spaced apart from the first active pattern in the second direction and electrically connected to the first bitline.

13. The semiconductor memory device of claim 12, wherein the third active pattern is electrically connected to the first data storage pattern and not electrically connected to the second data storage pattern.

14. The semiconductor memory device of claim 12, further comprising:
a second wordline between the first and third active patterns and extending in the third direction.

15. The semiconductor memory device of claim 10, further comprising:
a back gate electrode between the first and second bitlines and extending in the third direction,
wherein the first active pattern is between the first wordline and the back gate electrode.

16. The semiconductor memory device of claim 10, further comprising:
a contact pattern between the first data storage pattern and the first active pattern,
wherein the contact pattern overlaps the first bitline in the first direction and overlaps the second bitline in the third direction.

17. The semiconductor memory device of claim 16, further comprising:
a bitline spacer extending along a sidewall of the second bitline; and
a fence pattern extending in the third direction from the bitline spacer,
wherein the bitline spacer and the fence pattern extend around the contact pattern.

18. A semiconductor memory device, comprising:
first data storage patterns on a substrate;
second data storage patterns spaced apart from the first data storage patterns in a first direction perpendicular to an upper surface of the substrate;
first active patterns and second active patterns alternately disposed between the first data storage patterns and the second data storage patterns in a second direction parallel to the upper surface of the substrate and perpendicular to the first direction;
third active patterns and fourth active patterns alternately disposed in the second direction, wherein the third active patterns are spaced apart from the first active patterns in a third direction parallel to the upper surface of the substrate and perpendicular to both the first and second directions, and the fourth active patterns are spaced apart from the second active patterns in the third direction;
first bitlines between the first active patterns and the second data storage patterns, and between the third active patterns and the second data storage patterns, extending in the third direction, and electrically connected to the first active patterns and the third active patterns;
second bitlines between the second active patterns and the first data storage patterns, and between the fourth active patterns and the first data storage patterns, extending in the third direction, and electrically connected to the second active patterns and the fourth active patterns;
first wordlines adjacent to the first active patterns and the second active patterns in the third direction and extending in the second direction; and
second wordlines adjacent to the third active patterns and the fourth active patterns in the third direction and extending in the second direction,
wherein
the first active patterns and the third active patterns are electrically connected to the first data storage patterns, and
the second active patterns and the fourth active patterns are electrically connected to the second data storage patterns.

19. The semiconductor memory device of claim 18, wherein each of the first bitlines is between two of the second bitlines that are adjacent to each other in the second direction when viewed in a plan view.

20. The semiconductor memory device of claim 18, further comprising:
peripheral gate structures between the substrate and the first data storage patterns.
